(19) United States
(12) Patent Application Publication
(10) Pub. No.: US 2023/0217669 A1
(43) Pub. Date: Jul. 6, 2023

(54) LIGHT EMITTING DEVICE AND LIGHT EMITTING DISPLAY INCLUDING THE SAME

(71) Applicant: LG Display Co., Ltd., Seoul (KR)

(72) Inventors: Myeong Seon CHO, Paju-si (KR); Wook SONG, Paju-si (KR); Sae Mi PARK, Paju-si (KR); Jung Keun KIM, Paju-si (KR); Do Han KIM, Paju-si (KR); Byung Soo KIM, Paju-si (KR); Hye Seung KANG, Paju-si (KR)

(73) Assignee: LG Display Co., Ltd., Seoul (KR)

(21) Appl. No.: 18/082,583

(22) Filed: Dec. 16, 2022

(30) Foreign Application Priority Data
Dec. 31, 2021 (KR) 10-2021-0194744

(51) Int. Cl. H10K 50/13; H10K 50/12; H10K 50/15; H10K 50/16; H10K 59/35; H10K 85/60

(52) U.S. Cl. CPC H10K 50/13; H10K 50/12; H10K 50/15; H10K 50/16; H10K 59/351; H10K 85/654; H10K 85/6572; H10K 85/6574; H10K 85/6576; B82Y 30/00

(57) ABSTRACT

A light emitting device including a first electrode and a second electrode facing each other, and a first blue stack, a first charge generation layer, and a phosphorescent stack disposed between the first electrode and the second electrode. The phosphorescent stack includes a hole transport layer, a red light emitting layer, a green light emitting layer, and an electron transport layer. The red light emitting layer includes an electron transport host represented by Formula 1, a hole transport host different from the hole transport layer, and a red dopant.

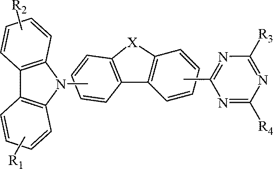

### CROSS-REFERENCE TO RELATED APPLICATION

This application claims the benefit of and the priority to Korean Patent Application No. 10-2021-0194744, filed on Dec. 31, 2021, which is hereby incorporated by reference as if fully set forth herein.

### BACKGROUND DISCLOSURE

### 1. Technical Field

The present disclosure relates to a light emitting device, and more particularly to a light emitting device that may be capable of improving efficiency of emission of white light and securing long-term stability. Thus, the lifespan may be prolonged by improving the exciton efficiency for each color equally or similarly in the phosphorescent stack by changing the material of the hole transport layer and the red light emitting layer of the phosphorescent stack adjacent to the blue stack. The present disclosure also relates to a light emitting display including the same.

### 2. Description of the Related Art

Recently, a light emitting display that does not require a separate light source and has a light emitting device in the display panel without a separate light source to make the display compact and realize clear color has been considered a competitive application.

Light emitting devices currently used in light emitting displays may require higher efficiency in order to realize desired image quality, and may be implemented in the form of a plurality of stacks. However, there may be a limitation on the extent to which efficiency may be increased using only a plurality of stacks due to differences in emission colors and emission principles between each stack. In addition, there may be a problem in that reliability may be lowered due to lack of consideration for stability when changing materials to increase efficiency.

### SUMMARY OF THE DISCLOSURE

Accordingly, the present disclosure is directed to a light emitting device and a light emitting display including the same that may substantially obviate one or more problems due to the limitations and disadvantages of the related art.

It is an object of the present disclosure to provide a light emitting device that may be capable of improving white efficiency and securing stability over time. The lifespan may be prolonged by equally improving the exciton efficiency for each color in the phosphorescent stack by changing the configuration of a hole transport layer and a red light emitting layer in a phosphorescent stack connected to a blue stack. It is another object of the present disclosure to provide a light emitting display including the light emitting device disclosed herein.

Objects of the present disclosure are not limited to the above-mentioned objects. Additional advantages, objects, and features of the disclosure that are not mentioned may be understood based on following descriptions, may be more clearly understood based on aspects of the present disclosure, and/or may be learned from practice of the disclosure. The objects and other advantages of the disclosure may be realized and attained by the structures described in the detailed description and claims as well as the appended drawings.

To achieve these and other advantages and in accordance with the objects of the disclosure, as embodied and broadly described herein, a light emitting device includes a first electrode and a second electrode facing each other, and a first blue stack, a first charge generation layer, and a phosphorescent stack disposed between the first electrode and the second electrode, wherein the phosphorescent stack includes a hole transport layer, a red light emitting layer, a green light emitting layer, and an electron transport layer, wherein the red light emitting layer includes an electron transport host represented by Formula 1, a hole transport host different from the hole transport layer, and a red dopant wherein the Formula 1 is:

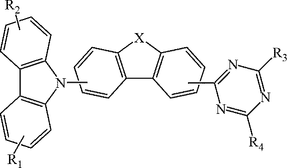

, and where at least one of Ri and R₂ is present, R₁ optionally forms a first fused ring together with the carbazole moiety in the Formula 1, R₂ optionally forms a second fused ring together with the carbazole moiety in the Formula 1, and Ri and R₂ are each an aromatic ring,

R₃ and R₄ are each selected from an aryl group, and a biphenyl group, and X is selected from N, O and S.

In another aspect of the present disclosure, a light emitting display includes a substrate including a plurality of subpixels, each of the subpixels includes a thin film transistor disposed therein, and the light emitting device according to example embodiments of the present disclosure connected to the thin film transistor.

It is to be understood that both the foregoing general description and the following detailed description of the present disclosure are merely by way of example and are intended to provide further explanation of the inventive concept as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure.

FIG. 1 illustrates a cross-sectional view of a light emitting device according to an example embodiment of the present disclosure.

FIG. 2 illustrates a cross-sectional view of the light emitting devices used in the first and second experimental example groups.

FIG. 3 is a graph showing the emission spectrum of the light emitting devices in the first experimental example group.

FIG. 4 is a graph showing the emission spectrum of the light emitting devices in the second experimental example group.

FIG. 5 illustrates generation of excitons in a configuration in which a phosphorescent light emitting layer is adjacent to a hole transport layer in a phosphorescent stack of the fourth experimental example.

FIG. 6 is a graph showing white emission spectra of light emitting devices of the six and seventh experimental examples having similar external quantum efficiencies.

FIG. 7 illustrates color coordinates (CIEx, CIEy) and luminance reduction rates when the light emitting devices of the six and seventh experimental examples are applied to a display.

FIG. 8 illustrates a cross-sectional view of the light emitting devices used for the eighth to tenth experimental examples of the present disclosure.

FIG. 9 is a graph showing the white emission spectra of the light emitting devices according to the eighth to tenth experimental examples.

FIG. 10 illustrates a cross-sectional view of a light emitting display including the light emitting device according to an example embodiment of the present disclosure.

### DETAILED DESCRIPTION

Reference will now be made in detail to example embodiments of the present disclosure, examples of which are illustrated in the accompanying drawings. Wherever possible, the same reference numbers will be used throughout the drawings to refer to the same or like parts, unless otherwise specified.

Advantages and features of the present disclosure, and a method of achieving the advantages and features will become apparent with reference to the example embodiments described herein in detail together with the accompanying drawings. The present disclosure should not be construed as limited to the example embodiments as disclosed below, and may be embodied in various different forms. Thus, these example embodiments are set forth only to make the present disclosure sufficiently complete, and to assist those skilled in the art to fully understand the scope of the present disclosure. The protected scope of the present disclosure is defined by the claims and their equivalents.

In the following description of the present disclosure, where the detailed description of the relevant known steps, elements, functions, technologies, and configurations may unnecessarily obscure an important point of the present disclosure, a detailed description of such steps, elements, functions, technologies, and configurations maybe omitted. In addition, the names of elements used in the following description are selected in consideration of clarity of description of the specification, and may differ from the names of elements of actual products. Furthermore, in the following detailed description of the present disclosure, numerous specific details are set forth in order to provide a sufficiently thorough understanding of the present disclosure. However, it will be understood that the present disclosure may be practiced without these specific details. In other instances, known methods, procedures, components, and circuits have not been described in detail so as not to unnecessarily obscure aspects of the present disclosure.

The shapes, sizes, ratios, angles, numbers, and the like, which are illustrated in the drawings to describe various example embodiments of the present disclosure are merely given by way of example. The disclosure is not limited to the illustrations in the drawings.

In the present specification, where terms such as “including,” “having,” “comprising,” and the like are used, one or more components may be added, unless the term, such as “only,” is used. As used herein, the term “and/or” includes a single associated listed item and any and all of the combinations of two or more of the associated listed items.

An expression such as “at least one of” when preceding a list of elements may modify the entire list of elements and may not modify the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In construing a component or numerical value, the component or the numerical value is to be construed as including an error or tolerance range even where no explicit description of such an error or tolerance range is provided.

In describing the various example embodiments of the present disclosure, where the positional relationship between two elements is described using terms, such as “on”, “above”, “under” and “next to”, at least one intervening element may be present between the two elements, unless “immediate(ly)” or “direct(ly)” or “close(ly) is used. It will be understood that when an element or layer is referred to as being “connected to”, or “coupled to” another element or layer, it may be directly connected to or coupled to the other element or layer, or one or more intervening elements or layers may be present.

In describing the various example embodiments of the present disclosure, when terms such as “after,” “subsequently,” “next,” and “before,” are used to describe the temporal relationship between two events, another event may occur therebetween , unless a more limiting term, such as “just,” “immediate(ly),” or “directly” is used.

In describing the various example embodiments of the present disclosure, terms such as “first” and “second” may be used to describe a variety of components. These terms aim to distinguish the same or similar components from one another and do not limit the components. Accordingly, throughout the specification, a “first” component may be the same as a “second” component within the technical concept of the present disclosure, unless specifically mentioned otherwise.

Features of various embodiments of the present disclosure may be partially or overall coupled to or combined with each other, and may be variously inter-operated with each other and driven technically as those skilled in the art can sufficiently understand. The embodiments of the present disclosure may be carried out independently from each other, or may be carried out together in a co-dependent relationship.

As used herein, the term “doped” layer refers to a layer including a first material and a second material (for example, n-type and p-type materials, or organic and inorganic substances) having physical properties different from the first material. Apart from the differences in properties, the first and second materials may also differ in terms of their amounts in the doped layer. For example, the host material may be a major component while the dopant material may be a minor component. The first material accounts for most of the weight of the doped layer. The second material may be added in an amount less than 30% by weight, based on a total weight of the first material in the doped layer. A “doped” layer may be a layer that is used to distinguish a host material from a dopant material of a certain layer, in consideration of the weight ratio. For example, if all of the materials constituting a certain layer are organic materials, at least one of the materials constituting the layer is n-type and the other is p-type, when the n-type material is present in an amount of less than 30 wt%, or when the p-type material is present in an amount of less than 30 wt%, the layer is considered to be a “doped” layer.

Also, the term “undoped” refers to layers that are not “doped”. For example, a layer may be an “undoped” layer when the layer contains a single material or a mixture including materials having the same properties as each other. For example, if at least one of the materials constituting a certain layer is p-type and none of the materials constituting the layer are n-type, the layer is considered to be an “undoped” layer. For example, if at least one of the materials constituting a layer is an organic material and none of the materials constituting the layer are inorganic materials, the layer is considered to be an “undoped” layer.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments of the present disclosure will be described in detail with reference to the accompanying drawings. In adding reference numerals to elements of each of the drawings, although the same elements are illustrated in other drawings, like reference numerals may refer to like elements. Also, for convenience of description, a scale in which each of elements is illustrated in the accompanying drawings may differ from an actual scale. Thus, the illustrated elements are not limited to the specific scale in which they are illustrated in the drawings.

Hereinafter, a light emitting device of the present disclosure and a light emitting display including the same will be described with reference to the drawings.

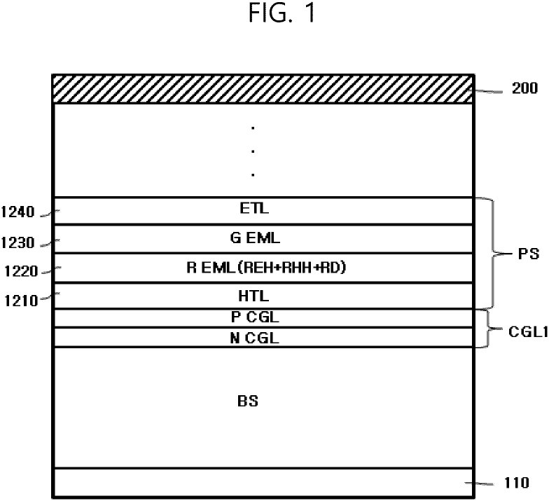

FIG. 1 illustrates a cross-sectional view of a light emitting device according to an example embodiment of the present disclosure.

As illustrated in the example embodiment of FIG. 1, the light emitting device according to the embodiment of the present disclosure includes a first electrode 110 and a second electrode 200 facing each other, and a first blue stack BS, a first charge generation layer CGL1 and a phosphorescent stack PS between the first electrode 110 and the second electrode 200.

In addition, the phosphorescent stack PS includes a hole transport layer 1210, a red light emitting layer 1220, a green light emitting layer 1230, and an electron transport layer 1240, wherein the red light emitting layer 1220 includes an electron transport host REH represented by Formula 1, a hole transport host RHH different from the hole transport layer 1210, and a red dopant RD.

Here, Formula 1 is given as follows.

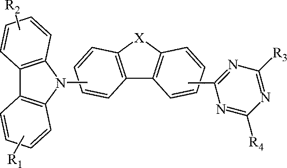

R₁ and R₂ are selected from an aromatic ring and a phenyl group.

R₃ and R₄ are each selected from an aryl group, a phenyl group, a naphthalene group, and a biphenyl group.

X is selected from N, O, and S.

The electron transport host REH included in the red light emitting layer 1220 is a benzocarbazole-based compound, and may correspond to, for example, the following BZC-01 to BZC-27.

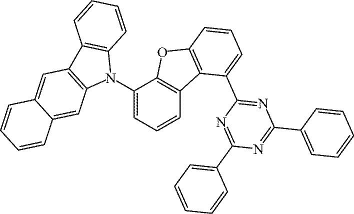 [SMILES: c1ccc(-c2nc(-c3ccccc3)nc(-c3cccc4oc5c(-n6c7ccccc7c7cc8ccccc8cc76)cccc5c34)n2)cc1]

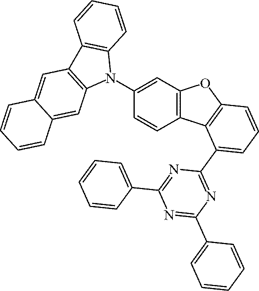 [SMILES: c1ccc(-c2nc(-c3ccccc3)nc(-c3cccc4oc5cc(-n6c7ccccc7c7cc8ccccc8cc76)ccc5c34)n2)cc1]

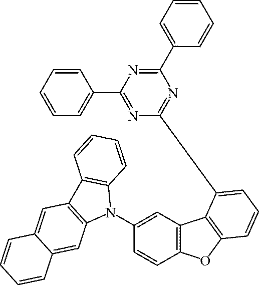 [SMILES: c1ccc(-c2nc(-c3ccccc3)nc(-c3cccc4oc5ccc(-n6c7ccccc7c7cc8ccccc8cc76)cc5c34)n2)cc1]

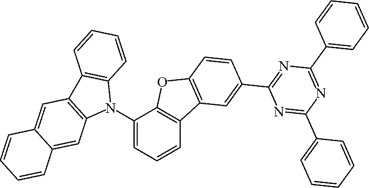 [SMILES: c1ccc(-c2nc(-c3ccccc3)nc(-c3ccc4oc5c(-n6c7ccccc7c7cc8ccccc8cc76)cccc5c4c3)n2)cc1]

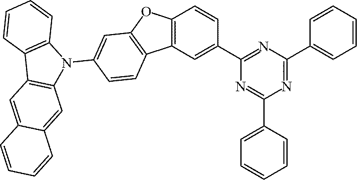 [SMILES: c1ccc(-c2nc(-c3ccccc3)nc(-c3ccc4oc5cc(-n6c7ccccc7c7cc8ccccc8cc76)ccc5c4c3)n2)cc1]

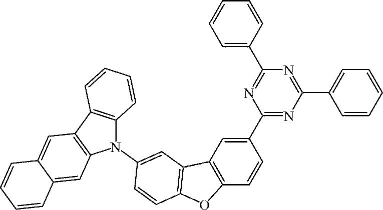 [SMILES: c1ccc(-c2nc(-c3ccccc3)nc(-c3ccc4oc5ccc(-n6c7ccccc7c7cc8ccccc8cc76)cc5c4c3)n2)cc1]

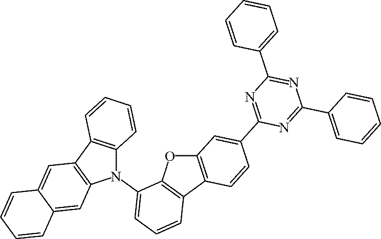 [SMILES: c1ccc(-c2nc(-c3ccccc3)nc(-c3ccc4c(c3)oc3c(-n5c6ccccc6c6cc7ccccc7cc65)cccc34)n2)cc1]

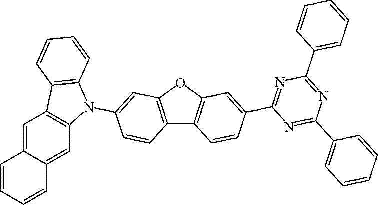 [SMILES: c1ccc(-c2nc(-c3ccccc3)nc(-c3ccc4c(c3)oc3cc(-n5c6ccccc6c6cc7ccccc7cc65)ccc34)n2)cc1]

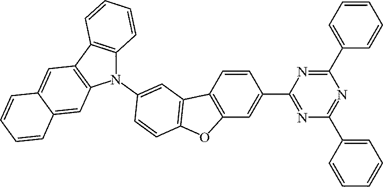 [SMILES: c1ccc(-c2nc(-c3ccccc3)nc(-c3ccc4c(c3)oc3ccc(-n5c6ccccc6c6cc7ccccc7cc65)cc34)n2)cc1]

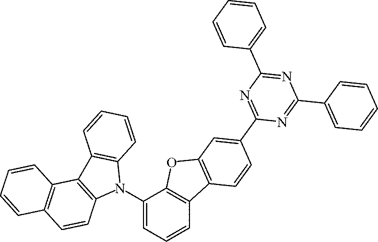 [SMILES: c1ccc(-c2nc(-c3ccccc3)nc(-c3ccc4c(c3)oc3c(-n5c6ccccc6c6c7ccccc7ccc65)cccc34)n2)cc1]

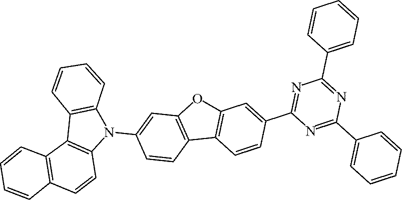 [SMILES: c1ccc(-c2nc(-c3ccccc3)nc(-c3ccc4c(c3)oc3cc(-n5c6ccccc6c6c7ccccc7ccc65)ccc34)n2)cc1]

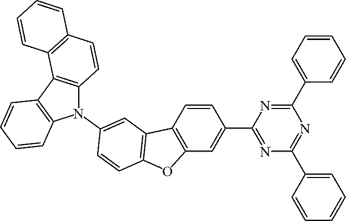 [SMILES: c1ccc(-c2nc(-c3ccccc3)nc(-c3ccc4c(c3)oc3ccc(-n5c6ccccc6c6c7ccccc7ccc65)cc34)n2)cc1]

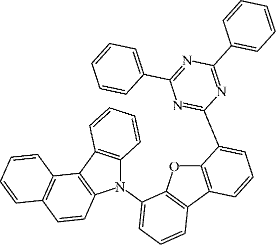 [SMILES: c1ccc(-c2nc(-c3ccccc3)nc(-c3cccc4c3oc3c(-n5c6ccccc6c6c7ccccc7ccc65)cccc34)n2)cc1]

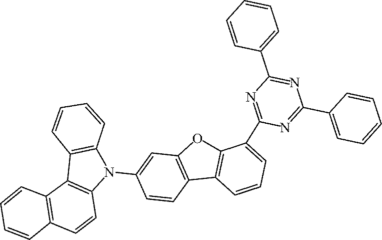 [SMILES: c1ccc(-c2nc(-c3ccccc3)nc(-c3cccc4c3oc3cc(-n5c6ccccc6c6c7ccccc7ccc65)ccc34)n2)cc1]

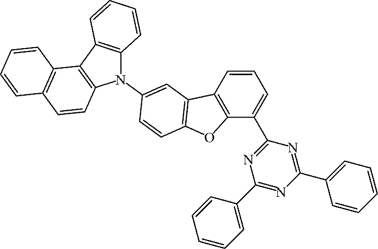 [SMILES: c1ccc(-c2nc(-c3ccccc3)nc(-c3cccc4c3oc3ccc(-n5c6ccccc6c6c7ccccc7ccc65)cc34)n2)cc1]

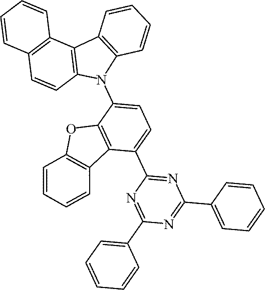 [SMILES: c1ccc(-c2nc(-c3ccccc3)nc(-c3ccc(-n4c5ccccc5c5c6ccccc6ccc54)c4oc5ccccc5c34)n2)cc1]

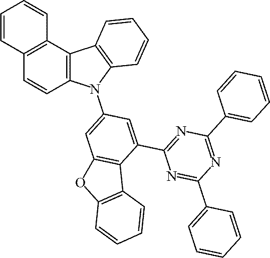 [SMILES: c1ccc(-c2nc(-c3ccccc3)nc(-c3cc(-n4c5ccccc5c5c6ccccc6ccc54)cc4oc5ccccc5c34)n2)cc1]

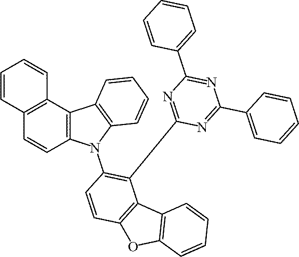 [SMILES: c1ccc(-c2nc(-c3ccccc3)nc(-c3c(-n4c5ccccc5c5c6ccccc6ccc54)ccc4oc5ccccc5c34)n2)cc1]

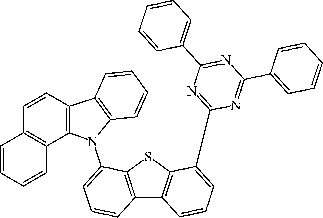 [SMILES: c1ccc(-c2nc(-c3ccccc3)nc(-c3cccc4c3sc3c(-n5c6ccccc6c6ccc7ccccc7c65)cccc34)n2)cc1]

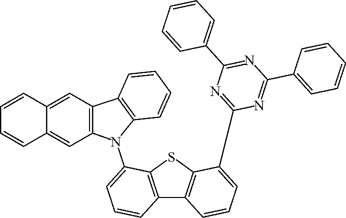 [SMILES: c1ccc(-c2nc(-c3ccccc3)nc(-c3cccc4c3sc3c(-n5c6ccccc6c6cc7ccccc7cc65)cccc34)n2)cc1]

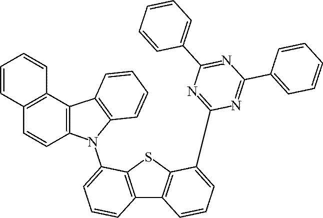 [SMILES: c1ccc(-c2nc(-c3ccccc3)nc(-c3cccc4c3sc3c(-n5c6ccccc6c6c7ccccc7ccc65)cccc34)n2)cc1]

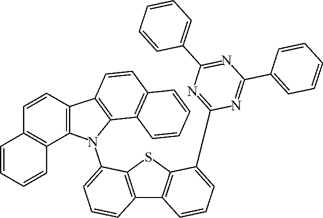 [SMILES: c1ccc(-c2nc(-c3ccccc3)nc(-c3cccc4c3sc3c(-n5c6c7ccccc7ccc6c6ccc7ccccc7c65)cccc34)n2)cc1]

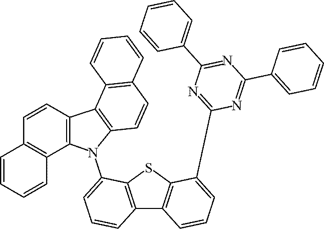 [SMILES: c1ccc(-c2nc(-c3ccccc3)nc(-c3cccc4c3sc3c(-n5c6ccc7ccccc7c6c6ccc7ccccc7c65)cccc34)n2)cc1]

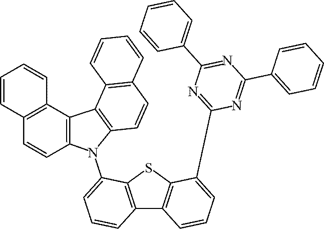 [SMILES: c1ccc(-c2nc(-c3ccccc3)nc(-c3cccc4c3sc3c(-n5c6ccc7ccccc7c6c6c7ccccc7ccc65)cccc34)n2)cc1]

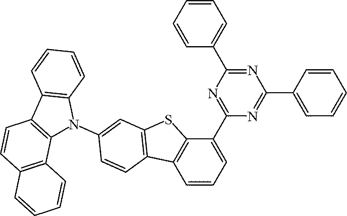 [SMILES: c1ccc(-c2nc(-c3ccccc3)nc(-c3cccc4c3sc3cc(-n5c6ccccc6c6ccc7ccccc7c65)ccc34)n2)cc1]

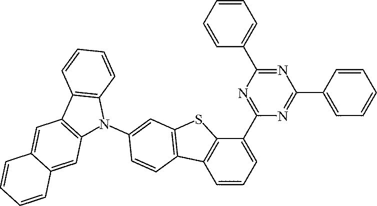 [SMILES: c1ccc(-c2nc(-c3ccccc3)nc(-c3cccc4c3sc3cc(-n5c6ccccc6c6cc7ccccc7cc65)ccc34)n2)cc1]

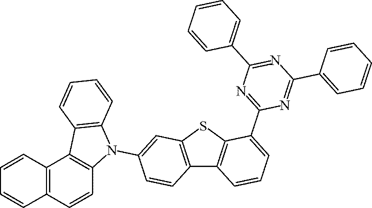 [SMILES: c1ccc(-c2nc(-c3ccccc3)nc(-c3cccc4c3sc3cc(-n5c6ccccc6c6c7ccccc7ccc65)ccc34)n2)cc1]

However, the benzocarbazole compounds described above are merely provided as examples. Any compound may be used as the electron transport host REH without limitation, so long as it corresponds to Formula 1, has similar thermal stability, acts as a host in the red light emitting layer 1220, and does not inhibit transport of holes to the green light emitting layer 1230, which is a phosphorescent light emitting layer.

The electron transport host REH included in the red light emitting layer 1220 of the present disclosure may have thermal stability. Therefore, when the hole transport host (RHH) and the electron transport host (REH) are co-deposited together, thermal damage may be distributed to both materials so that the formed red light emitting layer 1220 may exhibit thermal stability even a long time after deposition.

The hole transport host (RHH) uses or includes an amine-based compound that may be structurally and thermally stable so that when the red light emitting layer 1220 of the present disclosure uses or includes a benzocarbazole-based compound as the electron transport host (REH), comparable thermal stability may be secured.

In addition, although the electron transport host REH of the red light emitting layer 1220 of the present disclosure may have high electron transport efficiency, it may not interact with the adjacent hole transport layer 1210. The generation of excitons at the interface with the hole transport layer 1210 may be prevented or reduced. Internal exciton loss in the red light emitting layer 1220 and the green light emitting layer 1230 due to accumulation of excitons at the interface may be prevented or reduced. The light emitting device according to an example embodiment of the present disclosure may function to improve the efficiency of the red light emitting layer 1220 and to effectively transfer holes to the adjacent green light emitting layer 1230.

The red light emitting layer 1220 is disposed between the hole transport layer 1210 and the green light emitting layer 1230. The red light emitting layer 1220 may enable light emission through excitation of the red dopant (RD) through the interaction between the hole transport host (RHH) and the electron transport host (REH). The red light emitting layer 1220 may transfer holes not used to generate excitons back to the green light emitting layer 1230 by hole transport via the hole transport host RHH. Here, the electron transport host REH may have almost no overlap in the PL (photoluminescence) spectrum with the biscarbazole-based compound of the hole transport layer 1210. The electron transport host REH may undergo no or little interaction at the interface between the hole transport layer 1210 and the red light emitting layer 1220. Thus, generation of excitons at the interface may be prevented or reduced. Holes may be transferred from the hole transport layer 1210 to the red light emitting layer 1220 without a great energy barrier. Excitons between the inside of the red light emitting layer 1220 and the inside of the green light emitting layer 1230 may be generated.

To increase the efficiency of transport of holes to the red light emitting layer 1220 without causing interaction with the electron transport host (REH), the hole transport layer 1210 of the present disclosure is formed using a biscarbazole-based compound. The hole transport layer 1210 may include a biscarbazole-based compound. The biscarbazole-based compound used as or used in the hole transport layer 1210 is or may include a 3,3′biscarbazole-based compound, which may be represented by the following Formula 2.

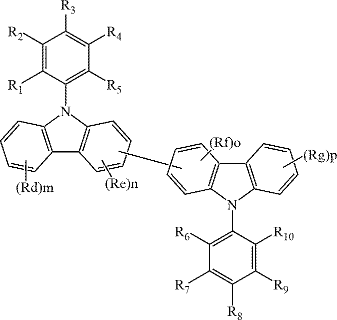

wherein Rd to Rg are each independently hydrogen, deuterium, halogen, a substituted or unsubstituted C1-C6 alkyl group, a substituted or unsubstituted C3-C6 cycloalkyl group, a substituted or unsubstituted C6-C15 aryl group, a substituted or unsubstituted C5-C9 heteroaryl group, a carbazole group, a dibenzofuran group, a dibenzothiophene group, a trialkylsilyl group, or a triarylsilyl group.

m, and p are each independently selected from integers from 0 to 4.

n and o are each independently selected from integers from 0 to 3.

In Formula 2, Ri to R₁₀ are each independently hydrogen, deuterium, halogen, a substituted or unsubstituted C1-C6 alkyl group, a substituted or unsubstituted C6-C15 aryl group such as a phenyl group, a phenanthrene group, and a triphenylene, a carbazole group, a N-phenyl carbazole group, a dibenzofuran group, or a dibenzothiophene group; or two or more of Ri to Rs and/or two or more of R₆ to R₉ may condense together with the adjacent phenyl to form a fused ring, for example, naphthalene, phenanthrene, triphenylene.

Also, examples of the 3,3′-biscarbazole include the following materials: BCA-01 to BCA-44.

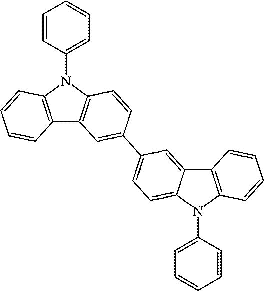 [SMILES: c1ccc(-n2c3ccccc3c3cc(-c4ccc5c(c4)c4ccccc4n5-c4ccccc4)ccc32)cc1]

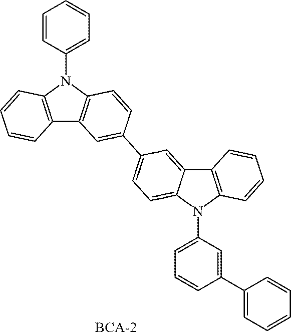

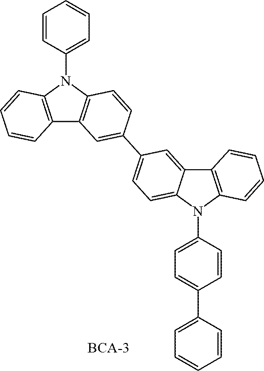

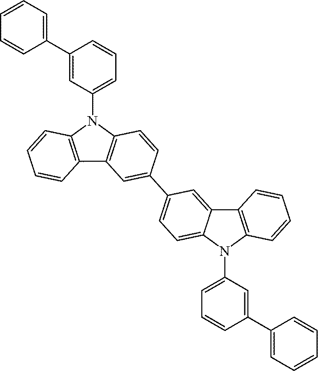 [SMILES: c1ccc(-c2cccc(-n3c4ccccc4c4cc(-c5ccc6c(c5)c5ccccc5n6-c5cccc(-c6ccccc6)c5)ccc43)c2)cc1]

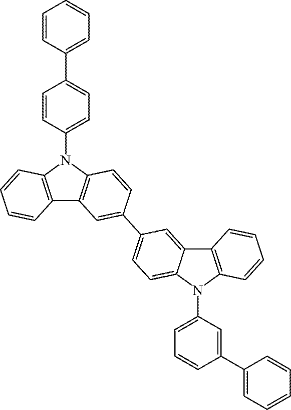 [SMILES: c1ccc(-c2ccc(-n3c4ccccc4c4cc(-c5ccc6c(c5)c5ccccc5n6-c5cccc(-c6ccccc6)c5)ccc43)cc2)cc1]

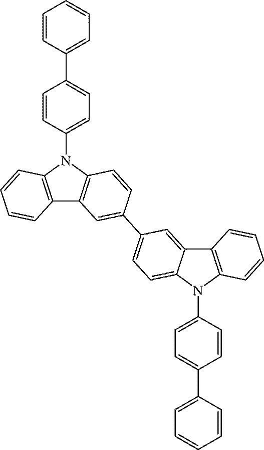 [SMILES: c1ccc(-c2ccc(-n3c4ccccc4c4cc(-c5ccc6c(c5)c5ccccc5n6-c5ccc(-c6ccccc6)cc5)ccc43)cc2)cc1]

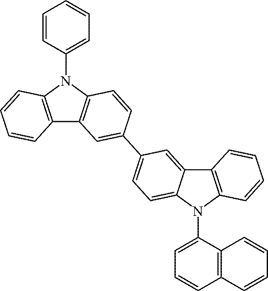 [SMILES: c1ccc(-n2c3ccccc3c3cc(-c4ccc5c(c4)c4ccccc4n5-c4cccc5ccccc45)ccc32)cc1]

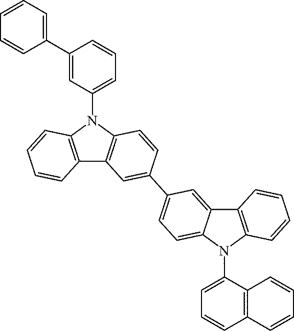 [SMILES: c1ccc(-c2cccc(-n3c4ccccc4c4cc(-c5ccc6c(c5)c5ccccc5n6-c5cccc6ccccc56)ccc43)c2)cc1]

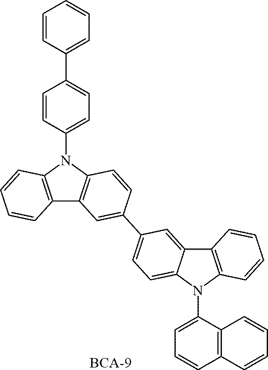

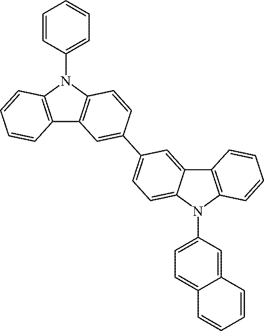 [SMILES: c1ccc(-n2c3ccccc3c3cc(-c4ccc5c(c4)c4ccccc4n5-c4ccc5ccccc5c4)ccc32)cc1]

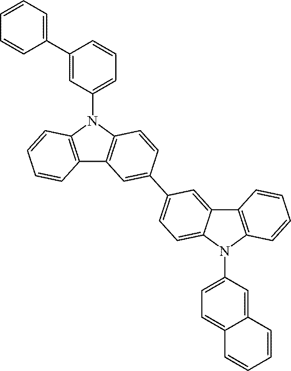 [SMILES: c1ccc(-c2cccc(-n3c4ccccc4c4cc(-c5ccc6c(c5)c5ccccc5n6-c5ccc6ccccc6c5)ccc43)c2)cc1]

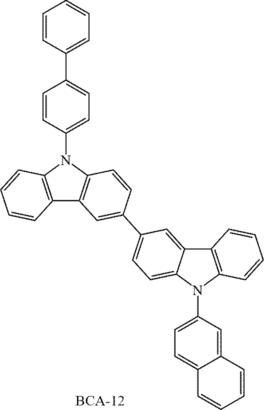

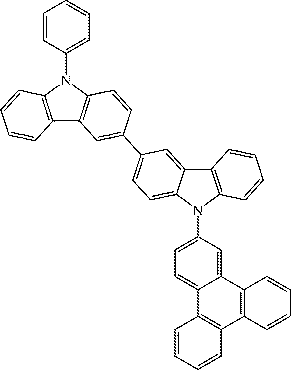 [SMILES: c1ccc(-n2c3ccccc3c3cc(-c4ccc5c(c4)c4ccccc4n5-c4ccc5c6ccccc6c6ccccc6c5c4)ccc32)cc1]

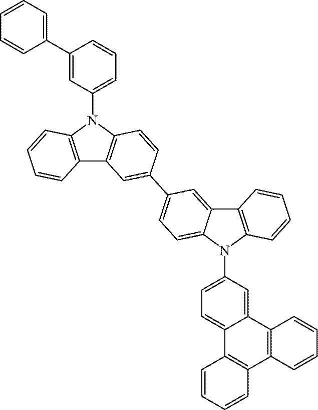 [SMILES: c1ccc(-c2cccc(-n3c4ccccc4c4cc(-c5ccc6c(c5)c5ccccc5n6-c5ccc6c7ccccc7c7ccccc7c6c5)ccc43)c2)cc1]

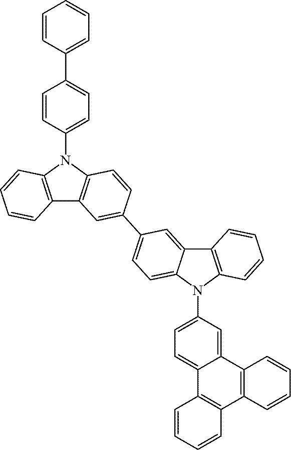 [SMILES: c1ccc(-c2ccc(-n3c4ccccc4c4cc(-c5ccc6c(c5)c5ccccc5n6-c5ccc6c7ccccc7c7ccccc7c6c5)ccc43)cc2)cc1]

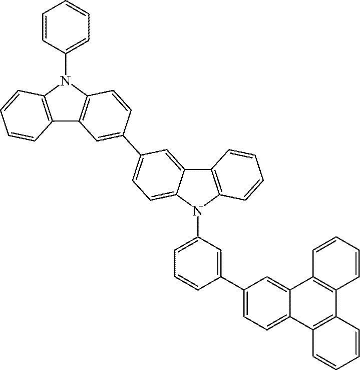 [SMILES: c1ccc(-n2c3ccccc3c3cc(-c4ccc5c(c4)c4ccccc4n5-c4cccc(-c5ccc6c7ccccc7c7ccccc7c6c5)c4)ccc32)cc1]

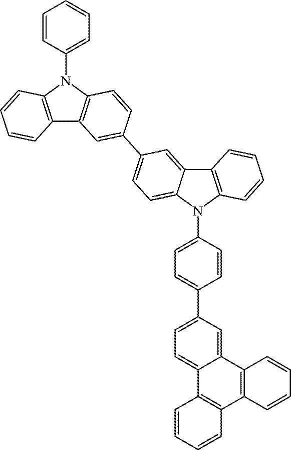 [SMILES: c1ccc(-n2c3ccccc3c3cc(-c4ccc5c(c4)c4ccccc4n5-c4ccc(-c5ccc6c7ccccc7c7ccccc7c6c5)cc4)ccc32)cc1]

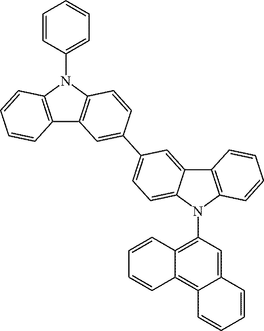 [SMILES: c1ccc(-n2c3ccccc3c3cc(-c4ccc5c(c4)c4ccccc4n5-c4cc5ccccc5c5ccccc45)ccc32)cc1]

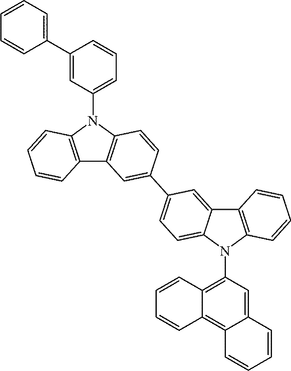 [SMILES: c1ccc(-c2cccc(-n3c4ccccc4c4cc(-c5ccc6c(c5)c5ccccc5n6-c5cc6ccccc6c6ccccc56)ccc43)c2)cc1]

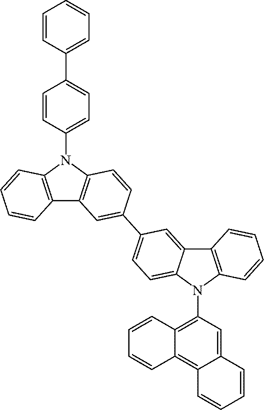 [SMILES: c1ccc(-c2ccc(-n3c4ccccc4c4cc(-c5ccc6c(c5)c5ccccc5n6-c5cc6ccccc6c6ccccc56)ccc43)cc2)cc1]

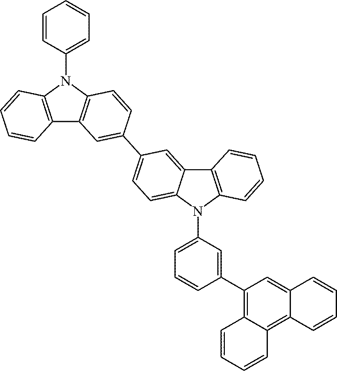 [SMILES: c1ccc(-n2c3ccccc3c3cc(-c4ccc5c(c4)c4ccccc4n5-c4cccc(-c5cc6ccccc6c6ccccc56)c4)ccc32)cc1]

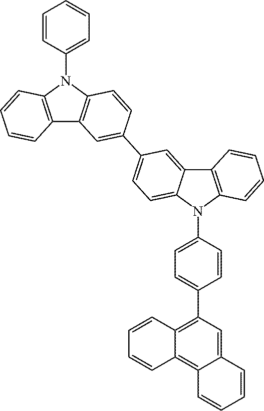 [SMILES: c1ccc(-n2c3ccccc3c3cc(-c4ccc5c(c4)c4ccccc4n5-c4ccc(-c5cc6ccccc6c6ccccc56)cc4)ccc32)cc1]

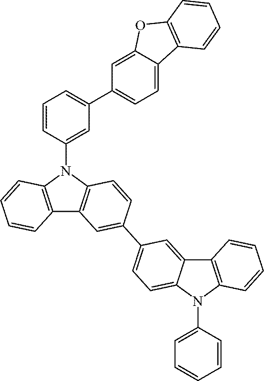 [SMILES: c1ccc(-n2c3ccccc3c3cc(-c4ccc5c(c4)c4ccccc4n5-c4cccc(-c5ccc6c(c5)oc5ccccc56)c4)ccc32)cc1]

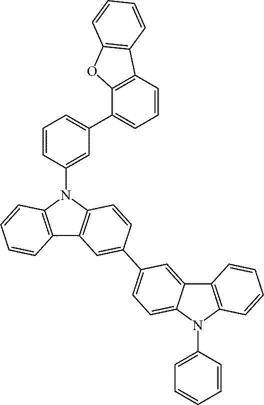 [SMILES: c1ccc(-n2c3ccccc3c3cc(-c4ccc5c(c4)c4ccccc4n5-c4cccc(-c5cccc6c5oc5ccccc56)c4)ccc32)cc1]

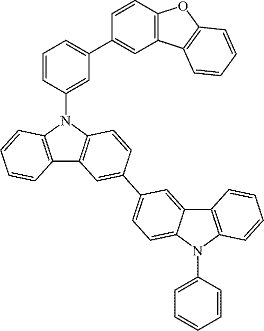 [SMILES: c1ccc(-n2c3ccccc3c3cc(-c4ccc5c(c4)c4ccccc4n5-c4cccc(-c5ccc6oc7ccccc7c6c5)c4)ccc32)cc1]

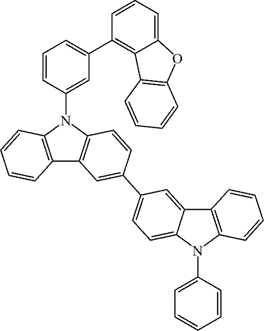 [SMILES: c1ccc(-n2c3ccccc3c3cc(-c4ccc5c(c4)c4ccccc4n5-c4cccc(-c5cccc6oc7ccccc7c56)c4)ccc32)cc1]

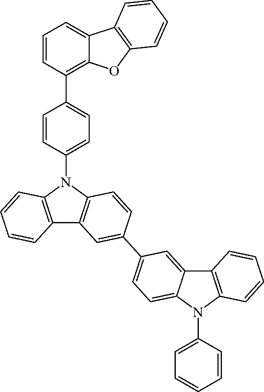 [SMILES: c1ccc(-n2c3ccccc3c3cc(-c4ccc5c(c4)c4ccccc4n5-c4ccc(-c5cccc6c5oc5ccccc56)cc4)ccc32)cc1]

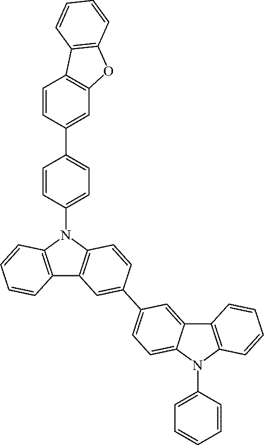 [SMILES: c1ccc(-n2c3ccccc3c3cc(-c4ccc5c(c4)c4ccccc4n5-c4ccc(-c5ccc6c(c5)oc5ccccc56)cc4)ccc32)cc1]

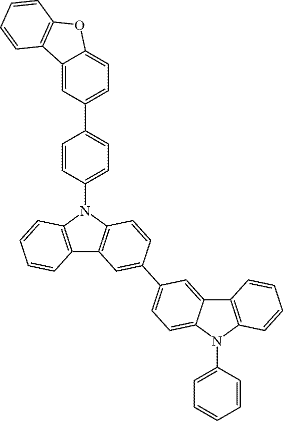 [SMILES: c1ccc(-n2c3ccccc3c3cc(-c4ccc5c(c4)c4ccccc4n5-c4ccc(-c5ccc6oc7ccccc7c6c5)cc4)ccc32)cc1]

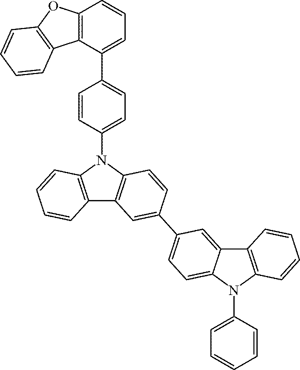 [SMILES: c1ccc(-n2c3ccccc3c3cc(-c4ccc5c(c4)c4ccccc4n5-c4ccc(-c5cccc6oc7ccccc7c56)cc4)ccc32)cc1]

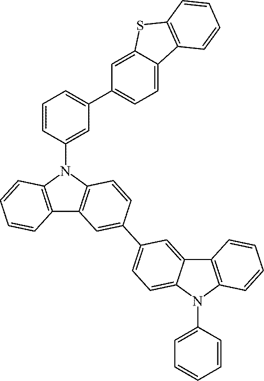 [SMILES: c1ccc(-n2c3ccccc3c3cc(-c4ccc5c(c4)c4ccccc4n5-c4cccc(-c5ccc6c(c5)sc5ccccc56)c4)ccc32)cc1]

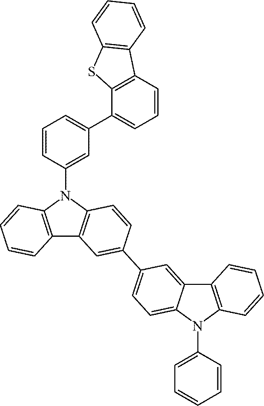 [SMILES: c1ccc(-n2c3ccccc3c3cc(-c4ccc5c(c4)c4ccccc4n5-c4cccc(-c5cccc6c5sc5ccccc56)c4)ccc32)cc1]

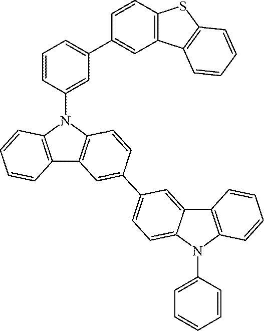 [SMILES: c1ccc(-n2c3ccccc3c3cc(-c4ccc5c(c4)c4ccccc4n5-c4cccc(-c5ccc6sc7ccccc7c6c5)c4)ccc32)cc1]

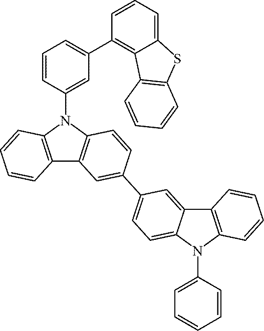 [SMILES: c1ccc(-n2c3ccccc3c3cc(-c4ccc5c(c4)c4ccccc4n5-c4cccc(-c5cccc6sc7ccccc7c56)c4)ccc32)cc1]

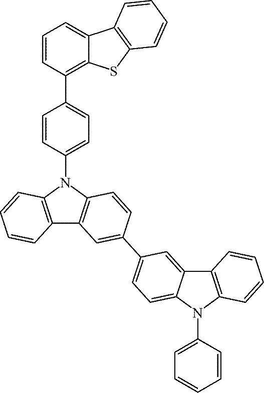 [SMILES: c1ccc(-n2c3ccccc3c3cc(-c4ccc5c(c4)c4ccccc4n5-c4ccc(-c5cccc6c5sc5ccccc56)cc4)ccc32)cc1]

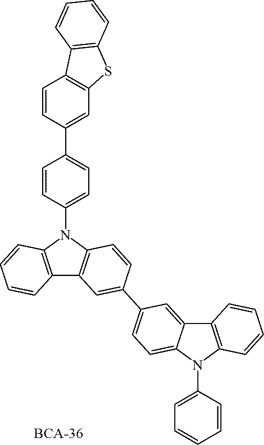

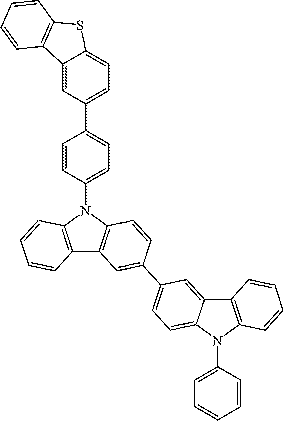 [SMILES: c1ccc(-n2c3ccccc3c3cc(-c4ccc5c(c4)c4ccccc4n5-c4ccc(-c5ccc6sc7ccccc7c6c5)cc4)ccc32)cc1]

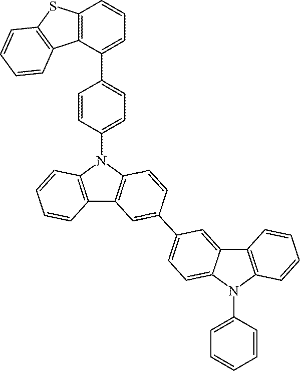 [SMILES: c1ccc(-n2c3ccccc3c3cc(-c4ccc5c(c4)c4ccccc4n5-c4ccc(-c5cccc6sc7ccccc7c56)cc4)ccc32)cc1]

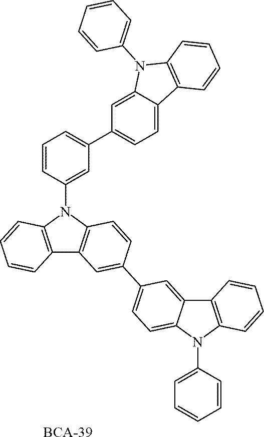

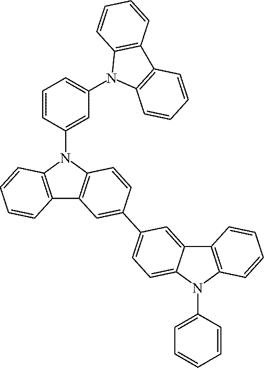 [SMILES: c1ccc(-n2c3ccccc3c3cc(-c4ccc5c(c4)c4ccccc4n5-c4cccc(-n5c6ccccc6c6ccccc65)c4)ccc32)cc1]

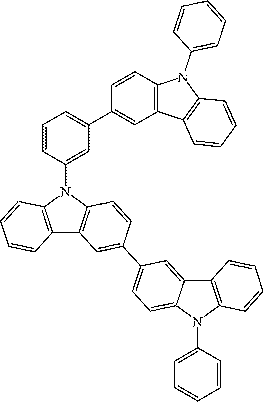 [SMILES: c1ccc(-n2c3ccccc3c3cc(-c4cccc(-n5c6ccccc6c6cc(-c7ccc8c(c7)c7ccccc7n8-c7ccccc7)ccc65)c4)ccc32)cc1]

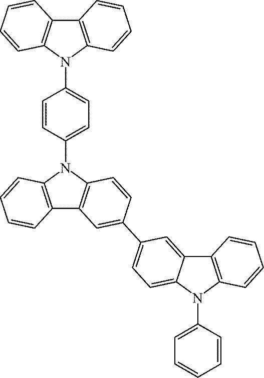 [SMILES: c1ccc(-n2c3ccccc3c3cc(-c4ccc5c(c4)c4ccccc4n5-c4ccc(-n5c6ccccc6c6ccccc65)cc4)ccc32)cc1]

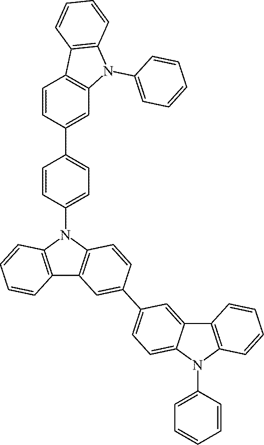 [SMILES: c1ccc(-n2c3ccccc3c3cc(-c4ccc5c(c4)c4ccccc4n5-c4ccc(-c5ccc6c7ccccc7n(-c7ccccc7)c6c5)cc4)ccc32)cc1]

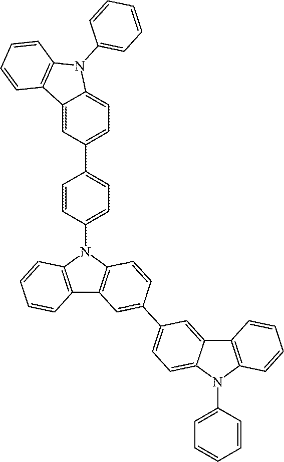 [SMILES: c1ccc(-n2c3ccccc3c3cc(-c4ccc(-n5c6ccccc6c6cc(-c7ccc8c(c7)c7ccccc7n8-c7ccccc7)ccc65)cc4)ccc32)cc1]

In the example embodiment of FIG. 1, the charge generation layer CGL1 in contact with the hole transport layer 1210 is a p-type charge generation layer P CGL containing an amine-based compound doped with a fluorene-based compound. A lower side of the phosphorescent stack PS of the light emitting device according to an example embodiment of the present disclosure may be adjacent to a blue stack BS. White light may be realized by combining light emitted from the blue stack BS with light emitted from the phosphorescent stack PS.

In addition, the charge generation layer CGL1 includes an n-type charge generation layer N CGL on a surface opposite the surface of the p-type charge generation layer P CGL that is in contact with the hole transport layer 1210. The n-type charge generation layer N CGL may be doped with an alkali metal, an alkaline earth metal, or a transition metal to smoothly supply the generated electrons to the blue stack BS.

The hole transport layer 1210 of the phosphorescent stack PS may have a thickness of 8 nm to 100 nm. Holes supplied from the p-type charge generation layer (P CGL) may be transferred from the hole transport layer 1210 to the red light emitting layer 1220 without interfacial accumulation. In addition, the hole transport layer 1210 has a predetermined thickness in order for the light emitting layers of the phosphorescent stack PS to have a proper distance for resonance from the first electrode 110.

In the example embodiment illustrated in the example embodiment of FIG. 1, the red light emitting layer 1220 and the green light emitting layer 1230 are in contact. However, a yellow-green light emitting layer may be further included between the red light emitting layer 1220 and the green light emitting layer 1230. Even in this case, the light emitting device according to an example embodiment of the present disclosure may exhibit the same or similar effect by changing the material of the hole transport layer 1210 and the material of the electron transport host of the red light emitting layer 1220.

The electron transport host may have a triplet energy level of 2.4 eV or less to provide smooth excitation operation of the red dopant (RD). The triplet energy level of the electron transport host may be 1.8 eV or higher.

In addition, at least one second blue stack including a blue light emitting layer may be included between the phosphorescent stack PS and the second electrode 200. This example embodiment aims to increase the efficiency of the blue light emitting layer formed as a fluorescent light emitting layer. This example embodiment may improve the blue efficiency in response to the required or desired high color temperature.

The significance of the light emitting device of the present disclosure was determined through the following experiments.

The following experiment was performed to determine the effects of the material of the electron transport host (REH) of the red light emitting layer 1220. The experiments on the first experimental example group (Ex1-1 to Ex1-14) and the second experimental example group (Ex2-1 to Ex2-27) were performed under the condition that the material of the hole transport layer 1210 was BCA-6, among the biscarbazole-based compounds, and the material of the electron transport host (REH) was varied.

In the first experimental example group (Ex1-1 to Ex1-14), the electron transport host of the red light emitting layer was selected from the following materials REH-1 to REH-14, and in the second experimental example group (Ex2-1 to Ex2-27), the above-described benzocarbazole-based BZC-1 to BZC-27 were used.

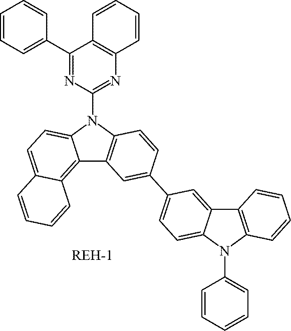

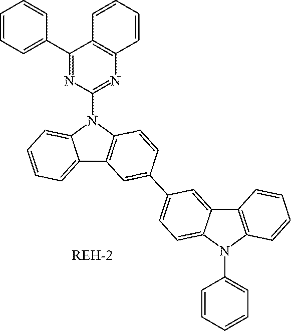

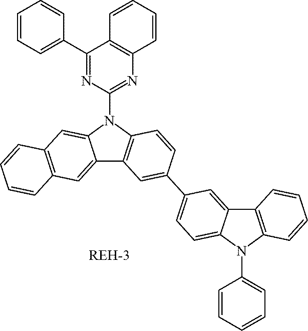

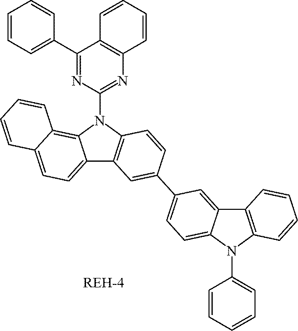

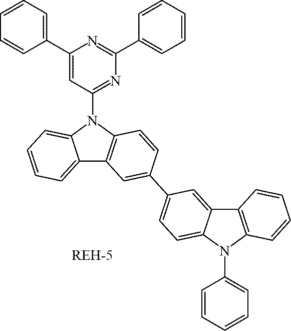

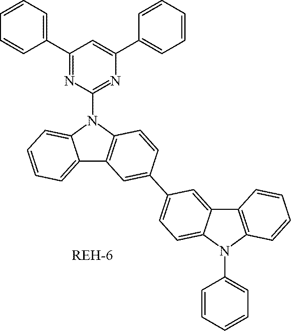

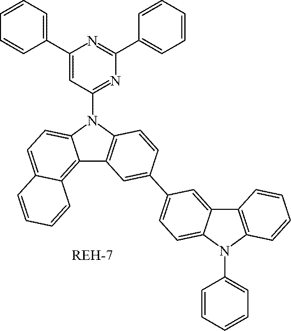

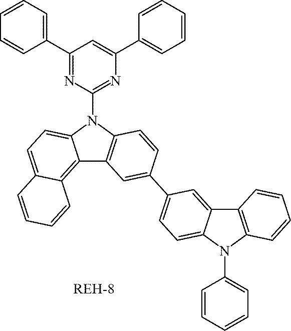

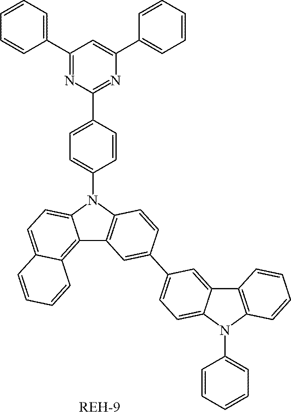

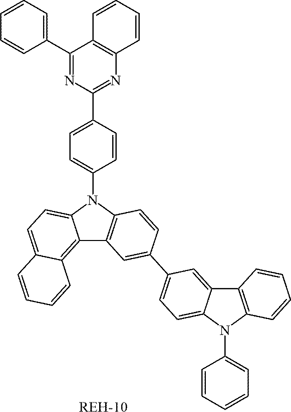

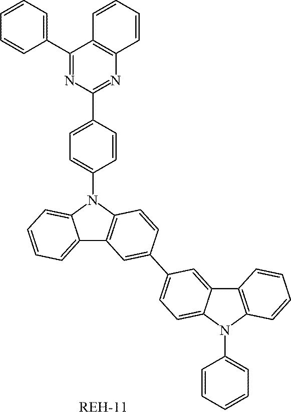

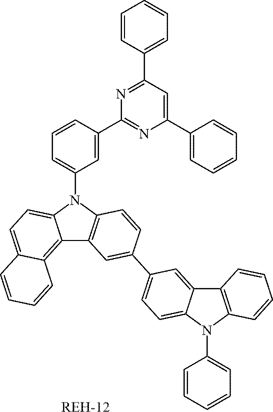

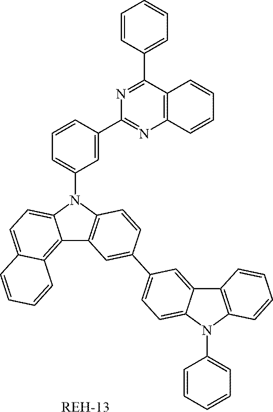

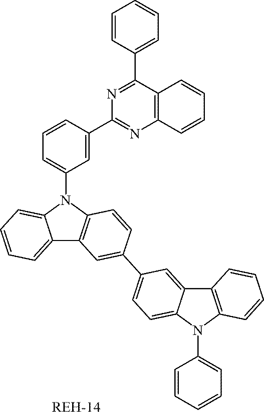

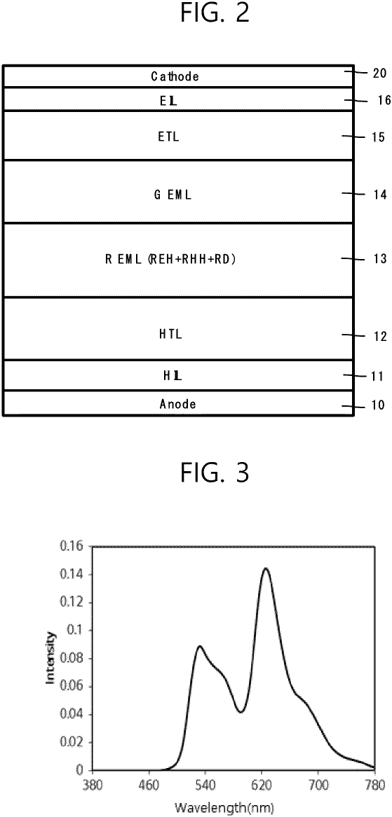

FIG. 2 illustrates a cross-sectional view of the light emitting devices used in the first and second experimental example groups.

The light emitting devices according to the first experimental example group were formed in accordance with the following process.

First, a first electrode 10 was formed on a substrate including ITO.

Then, DNTPD of Formula 3 shown below and MgF₂ were co-deposited at a weight ratio of 1:1 to a thickness of 7.5 nm to form a hole injection layer 11.

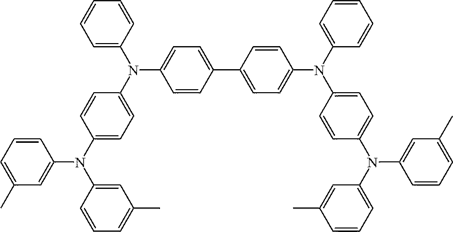 [SMILES: Cc1cccc(N(c2ccc(N(c3ccccc3)c3ccc(-c4ccc(N(c5ccccc5)c5ccc(N(c6cccc(C)c6)c6cccc(C)c6)cc5)cc4)cc3)cc2)c2cccc(C)c2)c1]

Then, the material of BCA-06 was deposited to a thickness of 10 nm to form a hole transport layer 12.

Then, a red light emitting layer 13 was formed to a thickness of 20 nm by doping a mixture including BPBPA of Formula 4 below as a hole transport host RHH and any one of REH-1 to REH-14 as an electron transport host at a ratio of 1:1 at 15 wt% with Ir(piq)₂(acac) of Formula 5. The red dopant may be replaced with another Iridium complex.

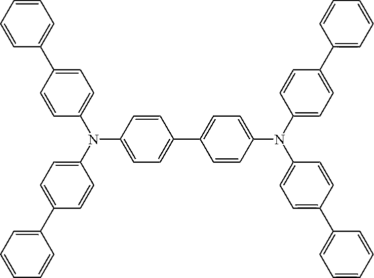 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1]

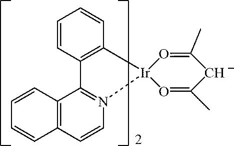

Then, a green light emitting layer 14 was formed to a thickness of 20 nm by doping a mixture including CBP of Formula 6 below and TPBi of Formula 7 below as a co-host at a ratio of 1:1 at 15 wt% with Ir(ppy)₃ of Formula 8. The green dopant may be replaced with another Iridium complex.

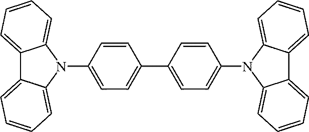 [SMILES: c1ccc2c(c1)c1ccccc1n2-c1ccc(-c2ccc(-n3c4ccccc4c4ccccc43)cc2)cc1]

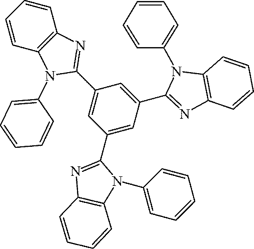 [SMILES: c1ccc(-n2c(-c3cc(-c4nc5ccccc5n4-c4ccccc4)cc(-c4nc5ccccc5n4-c4ccccc4)c3)nc3ccccc32)cc1]

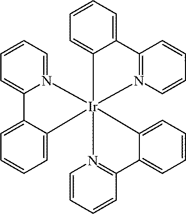

Then, TPBI is deposited to a thickness of 25 nm to form an electron transport layer 15.

Then, LiF was deposited to a thickness of 2 nm to form an electron injection layer 16.

Then, aluminum (Al) was deposited to form a second electrode 20.

In the experiments of the second experimental example group (Ex2-1 to Ex2-27), light emitting devices were formed under the condition that the electron transport host (REH) of the red light emitting layer 13 was changed to any one of the benzocarbazole-based BZC-1 to BZC-27, and the remaining conditions were the same as those of the first experimental example group (Ex1-1 to Ex1-14).

TABLE 1

| Item | REM (REH) | Voltage (V) | Efficiency (Cd/A) | EQE (%) | R_Cd/A | G_Cd/A | CIEx | CIEy |
|---|---|---|---|---|---|---|---|---|
| Ex1-1 | REH-1 | 3.38 | 42.6 | 23.6 | 10.2 | 14.4 | 0.503 | 0.516 |
| Ex1-2 | REH-2 | 3.42 | 41.1 | 23.1 | 10.1 | 13.7 | 0.507 | 0.513 |
| Ex1-3 | REH-3 | 3.46 | 40.7 | 22.0 | 9.4 | 14.0 | 0.498 | 0.522 |
| Ex1-4 | REH-4 | 3.38 | 36.8 | 21.4 | 9.6 | 11.9 | 0.515 | 0.506 |
| Ex1-5 | REH-5 | 3.45 | 39.3 | 22.1 | 9.7 | 13.1 | 0.506 | 0.514 |
| Ex1-6 | REH-6 | 3.40 | 40.4 | 22.6 | 9.9 | 13.5 | 0.506 | 0.514 |
| Ex1-7 | REH-7 | 3.50 | 39.2 | 22.5 | 10.0 | 12.9 | 0.512 | 0.509 |
| Ex1-8 | REH-8 | 3.48 | 38.8 | 21.9 | 9.6 | 12.9 | 0.508 | 0.512 |
| Ex1-9 | REH-9 | 3.46 | 43.9 | 23.7 | 10.1 | 15.1 | 0.497 | 0.522 |
| Ex1-10 | REH-10 | 3.46 | 43.0 | 23.5 | 10.1 | 14.7 | 0.500 | 0.519 |
| Ex1-11 | REH-11 | 3.47 | 41.7 | 23.4 | 10.3 | 13.9 | 0.507 | 0.513 |
| Ex1-12 | REH-12 | 3.40 | 41.8 | 23.3 | 10.2 | 14.0 | 0.505 | 0.515 |
| Ex1-13 | REH-13 | 3.45 | 39.0 | 21.7 | 9.4 | 13.1 | 0.504 | 0.516 |
| Ex1-14 | REH-14 | 3.51 | 40.0 | 22.0 | 9.5 | 13.6 | 0.502 | 0.518 |

As shown in Table 1, when the light emitting devices in the first experimental example group (Ex1-1 to Ex1-14) were formed using the electron transport host of the red light emitting layer, the color coordinates are formed based on the sum of red and green phosphorescent light, so CIEx is about 0.5 or more. This means that the efficiency of transfer of holes from the red light emitting layer 13 to the green light emitting layer 14 decreased. In particular, this means that when a white-light emitting device is formed in combination with a blue stack, the efficiency of green to realize white is greatly reduced. When the efficiency of white is adjusted to a desired level by compensating this reduction, the luminance of the light emitting display is greatly reduced.

Hereinafter, the results of the second experimental example group (Ex2-1 to Ex2-27) formed using a benzocarbazole-based compound as an electron transport host of the red light emitting layer will be described with reference to Table 2.

TABLE 2

| Item | REM (REH) | Voltage (V) | Efficiency (Cd/A) | EQE (%) | R Cd/A | G_Cd/A | CIEx | CIEy |
|---|---|---|---|---|---|---|---|---|
| Ex2-1 | BZC-1 | 3.43 | 49.6 | 22.9 | 8.5 | 18.9 | 0.461 | 0.556 |
| Ex2-2 | BZC-2 | 3.39 | 50.0 | 23.0 | 8.5 | 19.1 | 0.460 | 0.556 |
| Ex2-3 | BZC-3 | 3.39 | 48.9 | 22.7 | 8.5 | 18.6 | 0.463 | 0.554 |
| Ex2-4 | BZC-4 | 3.45 | 51.2 | 23.5 | 8.7 | 19.6 | 0.460 | 0.557 |
| Ex2-5 | BZC-5 | 3.42 | 51.7 | 23.7 | 8.8 | 19.8 | 0.460 | 0.557 |
| Ex2-6 | BZC-6 | 3.49 | 49.3 | 22.9 | 8.6 | 18.7 | 0.463 | 0.554 |
| Ex2-7 | BZC-7 | 3.39 | 51.2 | 23.5 | 8.7 | 19.6 | 0.460 | 0.557 |
| Ex2-8 | BZC-8 | 3.44 | 50.4 | 23.4 | 8.7 | 19.2 | 0.462 | 0.555 |
| Ex2-9 | BZC-9 | 3.50 | 50.6 | 23.3 | 8.6 | 19.4 | 0.460 | 0.556 |
| Ex2-10 | BZC-10 | 3.42 | 50.0 | 23.1 | 8.6 | 19.1 | 0.461 | 0.556 |
| Ex2-11 | BZC-11 | 3.47 | 50.4 | 23.5 | 8.8 | 19.2 | 0.463 | 0.554 |
| Ex2-12 | BZC-12 | 3.45 | 52.0 | 23.9 | 8.8 | 20.0 | 0.460 | 0.557 |
| Ex2-13 | BZC-13 | 3.42 | 51.1 | 23.7 | 8.8 | 19.5 | 0.462 | 0.555 |
| Ex2-14 | BZC-14 | 3.43 | 50.2 | 23.1 | 8.6 | 19.2 | 0.461 | 0.556 |
| Ex2-15 | BZC-15 | 3.38 | 50.1 | 23.1 | 8.6 | 19.1 | 0.461 | 0.556 |
| Ex2-16 | BZC-16 | 3.52 | 50.5 | 23.2 | 8.5 | 19.4 | 0.460 | 0.557 |
| Ex2-17 | BZC-17 | 3.47 | 50.0 | 23.3 | 8.7 | 19.0 | 0.463 | 0.554 |
| Ex2-18 | BZC-18 | 3.41 | 51.8 | 23.8 | 8.8 | 19.9 | 0.460 | 0.557 |
| Ex2-19 | BZC-19 | 3.43 | 50.3 | 23.1 | 8.5 | 19.3 | 0.460 | 0.557 |
| Ex2-20 | BZC-20 | 3.38 | 49.4 | 23.0 | 8.6 | 18.8 | 0.463 | 0.554 |
| Ex2-21 | BZC-21 | 3.41 | 50.0 | 23.2 | 8.7 | 19.0 | 0.462 | 0.555 |
| Ex2-22 | BZC-22 | 3.39 | 51.7 | 23.8 | 8.8 | 19.8 | 0.460 | 0.557 |
| Ex2-23 | BZC-23 | 3.50 | 50.4 | 23.4 | 8.7 | 19.2 | 0.462 | 0.555 |
| Ex2-24 | BZC-24 | 3.51 | 51.1 | 23.5 | 8.6 | 19.6 | 0.460 | 0.557 |
| Ex2-25 | BZC-25 | 3.50 | 49.5 | 23.0 | 8.6 | 18.9 | 0.462 | 0.555 |
| Ex2-26 | BZC-26 | 3.47 | 50.2 | 23.3 | 8.7 | 19.1 | 0.463 | 0.554 |
| Ex2-27 | BZC-27 | 3.39 | 50.2 | 23.1 | 8.5 | 19.2 | 0.460 | 0.556 |

As shown in Table 2, when a benzocarbazole compound was used as the electron transport host of the red light emitting layer in the second experimental example group (Ex2-1 to Ex2-27), the CIEx, when the light emitting device according to the example embodiment of FIG. 2 was manufactured, is about 0.46, which is about 0.04 lower than that of the first experiment example group (Ex1-1 to Ex1-14). In addition, it may be seen that in the second experimental example group (Ex2-1 to Ex2-27), red light emission efficiency decreased and green light emission efficiency increased. However, in the second experimental example group (Ex2-1 to Ex2-27), green light emission efficiency increased and overall luminance efficiency improved. This means that, when a light emitting device that realizes white in combination with a blue stack is formed, the efficiency of green light emission, which contributes the most to overall luminance, is greatly improved, so high efficiency of white may be obtained without using a compensation means other than the light emitting device.

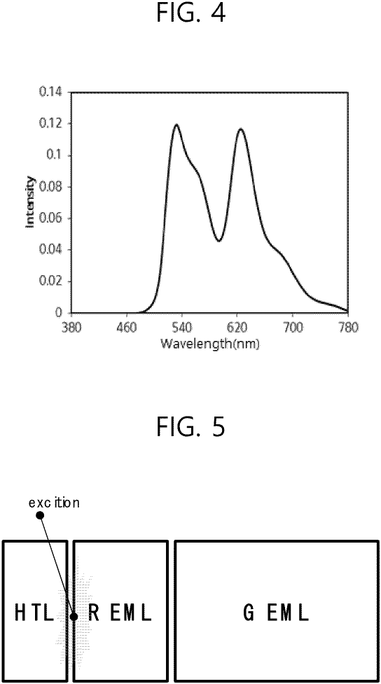

FIG. 3 is a graph showing the emission spectrum of the light emitting devices in the first experimental example group. FIG. 4 is a graph showing the emission spectrum of the light emitting devices in the second experimental example group.

From the emission spectra illustrated in FIGS. 3 and 4, it may be seen that the red light emission efficiency and the green emission spectrum are different due to the difference in the electron transport host of the red light emitting layer. In the emission spectra of the light emitting devices of the first experimental example group (Ex1-1 to Ex1-14) as illustrated FIG. 3, it may be seen that the overall red light emission efficiency is greatly improved, but green light emission efficiency is decreased.

In the emission spectra of the light emitting devices of the second experimental example group (Ex2-1 to Ex2-27) as illustrated in FIG. 4, red and green light emissions are equally or similarly improved. This means that when the second experimental example group (Ex2-1 to Ex2-27) is incorporated into a light emitting device, red and green light emission may be appropriately obtained with the phosphorescent stack itself without using a separate compensation means when a white-light emitting device is formed in combination with a blue stack. The light emitted from the light emitting device may be used to the greatest extent possible.

In the above-described first and second experimental example groups, BPBPA was used as the hole transport host (RHH) of the red light emitting layer, but the light emitting device of the present disclosure is not limited thereto. Instead of BPBPA, any compound may be used, so long as it may be capable of performing an operation for red light emission together with an electron transport host including the benzocarbazole-based compound of Formula 1 in the red light emitting layer (R EML) and may function to transfer holes to the green light emitting layer (G EML). Accordingly, an amine-based material, such as BPBPA, may be used, and the above-described biscarbazole-based compound may also be used. For example, if the material for the hole transport layer in contact with the red light emitting layer is formed of or includes any one of BCA-1 to BCA-44 biscarbazole-based materials, the hole transport host of the red light emitting layer may be a biscarbazole-based material different from the material selected for the hole transport layer.

Hereinafter, a reason for the difference in efficiencies of red and green light emission depending on the material of the host transport host of the hole transport layer and the material of the electron transport host of the red light emitting layer will be determined.

As shown in Table 3, the phenomenon occurring at the interface between the hole transport layer and the red light emitting layer will be observed while changing the material of the hole transport host of the hole transport layer and the material of the electron transport host of the red light emitting layer.

FIG. 5 illustrates generation of excitons in a configuration in which a phosphorescent light emitting layer is adjacent to a hole transport layer in a phosphorescent stack according to the fourth experimental example.

TABLE 3

| | | | |
|---|---|---|---|
| Structure | Ex3 | Ex4 | Ex5 |
| Hole transport layer (HTL) | BPBPA | BPBPA | BCA-6 |
| Electron transport host in red light emitting layer (REH) | REH-1 | BZC-01 | BZC-01 |
| External quantum efficiency | Excellent | Deteriorated | Excellent |
| REH thermal stability | Low | Excellent | Excellent |

As shown in Table 3, in the third experimental example (Ex3), BPBPA is used as the hole transport layer (HTL) and REH-1 is used as the electron transport host (REH) in the red light emitting layer. As tested in the first experimental example group, the material of REH-1 may improve red light emission efficiency through high external quantum efficiency, but may have low material stability because it may have an electron cloud imbalance due to the asymmetric structure of pyridine and pyrimidine. Accordingly, when the process time or process temperature is increased, due to low stability, material degradation occurs. Thus, the material may be inapplicable to a red light emitting layer that exhibits long-term stability. In the fourth experimental example (Ex4), BZC-01 was used as the electron transport host (REH) in the red light emitting layer (R EML). As illustrated in the example embodiment of FIG. 5, interactive light emission action may occur between BPBPA, which is the material of the hole transport layer (HTL), and an electron transport host. The holes transferred from the hole transport layer may combine with electrons from the red light emitting layer to generate excitons at the interface between the hole transport layer (HTL) and the red-light emitting layer (R EML). In this case, some excitons that should act inside the red light emitting layer (R EML) and the green light emitting layer (G EML) may be generated at the interface between the hole transport layer (HTL) and the red light emitting layer (R EML). Thus, exciton loss may occur. Actual external quantum efficiency may be reduced.

In the fifth experimental example (Ex5), BCA-6, which is a biscarbazole-based compound having a hole transport function without interaction with the material of the red light emitting layer, was used as a hole transport layer in the light emitting device according to an example embodiment of the present disclosure, and BZC-01 was used as an electron transport host (REH) in the red light emitting layer. In this case, the electron transport host REH may have high thermal stability and thus may undergo no or little deformation over time after the formation of the red light emitting layer. The electron transport host REH may exhibit thermal stability and receive holes without interaction with the hole transport layer. The excitons may be well distributed in the red light emitting layer (R EML) and the green light emitting layer (G EML) without exciton accumulation at the interface between the hole transport layer and the red light emitting layer. Thus, both the red light emitting layer and the green light emitting layer may exhibit high light emission efficiency.

Hereinafter, the necessity of compensation in the white light emitting device depending on the efficiency of emission of each color and improvement in green light emission efficiency in the light emitting device according to an example embodiment of the present disclosure will be investigation through the sixth and seventh experimental examples, in which external quantum efficiencies are similar but efficiency of emission of red and green light is different.

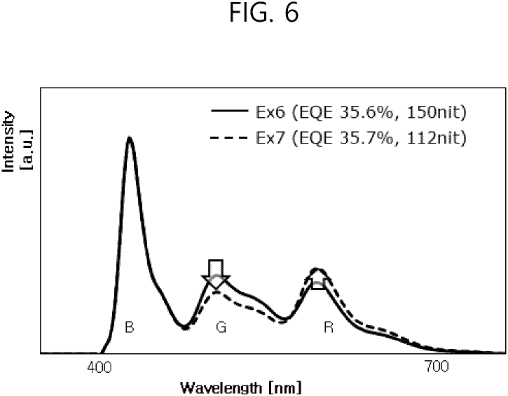

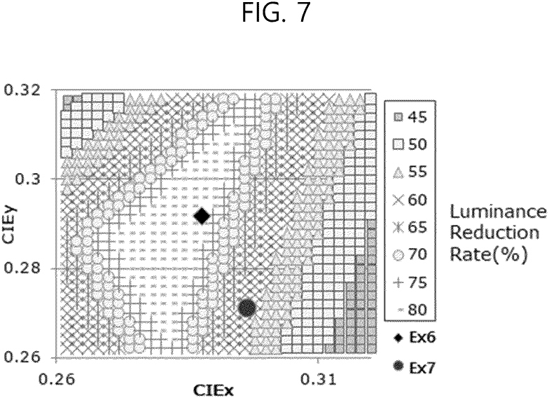

FIG. 6 is a graph showing white emission spectra of light emitting devices of the sixth and seventh experimental examples having similar external quantum efficiencies. FIG. 7 illustrates color coordinates (CIEx, CIEy) and luminance reduction when the light emitting devices of the sixth and seventh experimental examples are applied to a display.

FIG. 6 compares the sixth experimental example (Ex6), in which green and red efficiencies are uniform like the experimental results of the second experimental example group, with the seventh experimental example (Ex7), in which red light emission efficiency is higher than green light emission efficiency similar to the first experimental example group.

In the sixth experimental example (Ex6) and the seventh experimental example (Ex7), the blue stack is identically configured so as to be adjacent to the first electrode 10 and the second electrode 20, respectively, in the configuration of the light emitting device according to the example embodiment illustrated in FIG. 2.

The sixth experimental example (Ex6) and the seventh experimental example (Ex7) have similar external quantum efficiencies of 35.6% and 35.7%. But the seventh experimental example (Ex7) has higher red light emission efficiency than green light emission efficiency because light emission is mostly based on the red light emitting layer.

Considering the color coordinates (CIEx, CIEy) of white produced when a white light emitting device is formed in combination with the same blue stack of the light emitting device according to the sixth experimental example (Ex6) and the seventh experimental example (Ex7), the color coordinates of white for the sixth experimental example (Ex6) and the seventh experimental example (Ex7) are (0.286, 0.292) and (0.296, 0.272), respectively. The seventh experimental example (Ex7) has higher CIEx due to the high red light emission efficiency of the white light emitting device.

For a light emitting display to actually display a sufficiently broad color gamut, the green luminance efficiency may occupy the largest portion of the total white luminance efficiency compared to other colors in expressing white. Accordingly, a light emitting device having low green light emission efficiency may need to be compensated through a circuit of the light emitting display, and luminance may be reduced due to adjusting each color.

FIG. 7 illustrates a luminance reduction rate for each color coordinate when applied to a light emitting display. The sixth experimental example (Ex6), which has high green light emission efficiency, exhibits a luminance reduction rate of about 80%. The seventh experimental example (Ex7), which has high red light emission efficiency, exhibits a luminance reduction rate of about 60%, which indicates that there is a luminance decrease.

In the sixth experimental example (Ex6), the light emitting device according to an example embodiment of the present disclosure may be capable of maximizing the efficiency thereof by adjusting the overall color balance of a white-light emitting device to make the efficiency of green and red similar to each other.

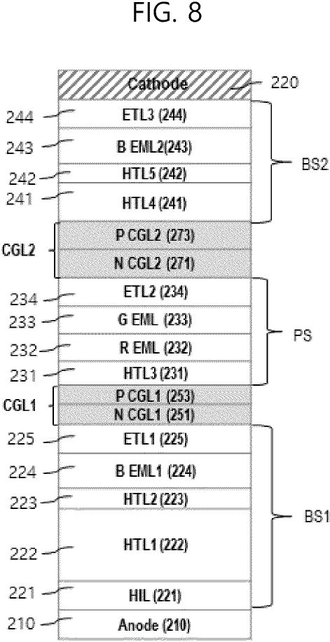

Hereinafter, the characteristics of the light emitting device according to example embodiments of the present disclosure will be described with reference to the example embodiments of the eighth to tenth experimental examples applied to the white-light emitting device having the structure illustrated in FIG. 8.

FIG. 8 illustrate a cross-sectional view of the light emitting devices used in the eighth to tenth experimental examples of the present disclosure.

As illustrated in the example embodiment of FIG. 8, the light emitting device for the eighth to tenth experimental examples has the same blue stack structure adjacent to the first electrode and the second electrode, respectively, in the light emitting device configuration illustrated in the example embodiment of FIG. 2. The light emitting device for the eighth experimental example was formed in accordance with the following process.

First, a first electrode 210 was formed on a substrate including ITO.

As a first blue stack BS1, a hole injection layer (HIL) 221 was first formed to a thickness of 5 nm on the first electrode 210 using MgF₂.

Then, DNTPD was deposited to a thickness of 100 nm to form a first hole transport layer 222.

Then, TCTA of Formula 9 below was deposited to a thickness of 5 nm to form a second hole transport layer 223.

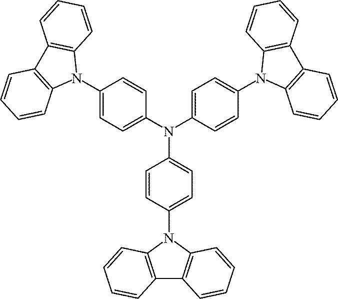 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1]

Then, a first blue light emitting layer 224 was formed to a thickness of 20 nm by doping MADN of Formula 10 below as a host with DABNA-1 of Formula 11 below at 5 wt%.

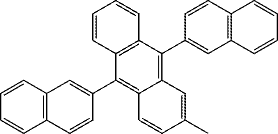 [SMILES: Cc1ccc2c(-c3ccc4ccccc4c3)c3ccccc3c(-c3ccc4ccccc4c3)c2c1]

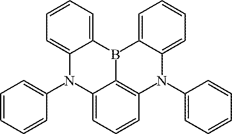 [SMILES: c1ccc(N2c3ccccc3B3c4ccccc4N(c4ccccc4)c4cccc2c43)cc1]

Then, a first electron transport layer 225 was formed to a thickness of 15 nm using an electron transporting material such as ZADN.

Then, a first n-type charge generation layer 251 was formed to a thickness of 15 nm by doping Bphen of Formula 12 below as a host with Li at 2 wt%.

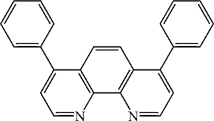 [SMILES: c1ccc(-c2ccnc3c2ccc2c(-c4ccccc4)ccnc23)cc1]

Then, a first p-type charge generation layer 253 was formed to a thickness of 7 nm by doping DNTPD as a host with a p-type dopant at 20 wt%.

The first n-type charge generation layer 251 and the first p-type charge generation layer 253 were stacked to form a first charge generation layer CGL1.

The phosphorescent stack PS is similar to that described with reference to FIG. 2. A third hole transport layer 231 was formed to a thickness of 20 nm by changing the material to the above-described BPBPA or BCA-6.

Then, a red light emitting layer 232 was formed to a thickness of 20 nm by doping a co-host, that is, BPBPA as a hole transport host RHH, and REH-1 or BZC-02 as an electron transport host REH at a ratio of 1:1 at 5 wt% with Ir(ppy)₃.

Then, a green light emitting layer 233 was formed to a thickness of 20 nm by doping a mixture including CBP and TPBi as a co-host at a ratio of 1:1 at 15 wt% with Ir(ppy)₃.

Then, TPBi was deposited to a thickness of 20 nm to form a second electron transport layer 234.

Then, a second n-type charge generation layer 271 was deposited to a thickness of 20 nm by doping Bphen as a host at 3 wt% with Li.

Then, a second p-type charge generation layer 273 was formed to a thickness of 10 nm by doping DNTPD as a host at 20 wt% with a p-type dopant.

The second n-type charge generation layer 271 and the second p-type charge generation layer 273 were stacked to form a second charge generation layer CGL2.

Then, a second blue stack BS2 was formed by forming a hole transport layer 242, a second blue light emitting layer 243, and a third electron transport layer 244 in the manner similar to the configuration including the first hole transport layer 222 to the first electron transport layer 225 of the first blue stack BS1.

Then, LiF was deposited to a thickness of 1.5 nm to form an electron injection layer. Then, Al was deposited to a thickness of 100 nm to form a cathode 220.

TABLE 4

| | | |
|---|---|---|
| Item | HTL3 | REH |
| Ex8 | BPBPA | BZC-02 |
| Ex9 | BCA-6 | REH-1 |
| Ex10 | BCA-6 | BZC-02 |

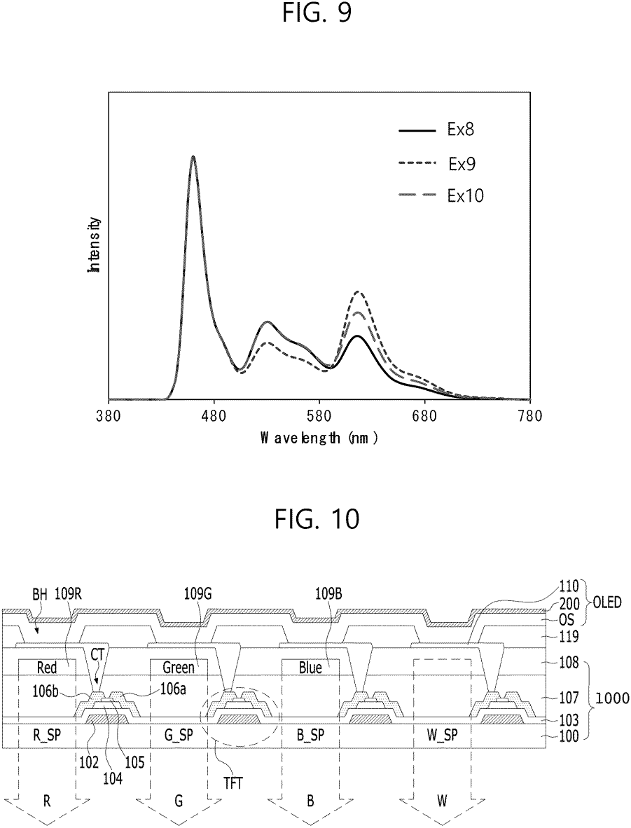

As shown in Table 4, in the eighth to tenth experimental examples (Ex8, Ex9, Ex10), and as illustrated in the example embodiment of FIG. 8, the hole transport layer (HTL3) and the electron transport host (REH) of the red light emitting layer in contact with the phosphorescent stack were changed. FIG. 9 is a graph showing the white emission spectra of the light emitting devices of the eight to tenth experimental examples.

Table 5 shows the driving voltage, external quantum efficiency, and efficiency of emission of each color of the eighth to tenth experimental examples (Ex8, Ex9, Ex10), and Table 6 shows the color coordinates of red, green, blue, and white.

TABLE 5

| Item | Voltage [V] | EQE(%) | R efficiency [Cd/A] | G efficiency [Cd/A] | B efficiency [Cd/A] | W efficiency [Cd/A] |
|---|---|---|---|---|---|---|
| Ex8 | 11.4 | 27.9 | 6.8 | 23.3 | 4.6 | 58.9 |
| Ex9 | 11.2 | 30.7 | 11.2 | 17.5 | 4.2 | 54.5 |
| Ex10 | 11.3 | 30.8 | 9.2 | 23.4 | 4.6 | 62.9 |

TABLE 6

| Item | Rx | Ry | Gx | Gy | Bx | By | Wx |
|---|---|---|---|---|---|---|---|
| Ex8 | 0.681 | 0.316 | 0.220 | 0.707 | 0.140 | 0.064 | 0.282 |
| Ex9 | 0.684 | 0.314 | 0.218 | 0.700 | 0.141 | 0.060 | 0.320 |
| Ex10 | 0.683 | 0.315 | 0.221 | 0.706 | 0.141 | 0.064 | 0.304 |

As can be seen from Tables 5 and 6, and FIG. 9, in the eighth experimental example (Ex8), when the material of the hole transport layer was not a biscarbazole compound, the overall efficiency is lower than that of the tenth experimental example (Ex10). In the ninth experimental example (Ex9), when the electron transport host (REH) of the red light emitting layer was not a benzocarbazole compound, which was described in the example embodiment of FIG. 5, exciton loss may have occurred at the interface between the hole transport layer and the red light emitting layer. Thus, red light emission efficiency increased but green light emission efficiency decreased. Thus, the overall white light emission efficiency decreased.

In the tenth experimental example (Ex10), when the hole transport layer in contact with the red light emitting layer was a biscarbazole compound and the electron transport host (REH) of the red light emitting layer is a benzocarbazole compound, the driving voltage did not increase. High external quantum efficiency was achieved and red and green efficiencies were equally increased, as illustrated in FIG. 9. The emission peak around 520 nm overlapped the emission peak around 520 nm for the eighth experimental example. The white color coordinates were also stable.

The light emitting device may be applied to a plurality of subpixels to emit white light toward a light emitting electrode.

FIG. 10 illustrates a cross-sectional view of a light emitting display including the light emitting device according to an example embodiment of the present disclosure.

As illustrated in the example embodiment of FIG. 10, the light emitting display of the present disclosure includes a substrate 100 having a plurality of subpixels R_SP, G_SP, B_SP, and W_SP, a light emitting device (also referred to as an “OLED, organic light emitting diode”) provided on the substrate 100, a thin film transistor (TFT) provided in each of the subpixels and connected to the first electrode 110 of the light emitting device (OLED), and color filters 109R, 109G, or 109B provided below the first electrode 110 for at least one of the subpixels. The OLED includes an internal stack OS including, for example, at least one blue stack and a phosphorescent stack.

The illustrated example embodiment relates to a configuration including the white subpixel W_SP, but the present disclosure is not limited thereto. A configuration in which the white subpixel W_SP is omitted and only the red, green, and blue subpixels R_SP, G_SP, and B_SP are provided is also possible. In some cases, a combination of a cyan subpixel, a magenta subpixel, and a yellow subpixel capable of creating white may be used instead of the red, green, and blue subpixels.

The thin film transistor TFT includes, for example, a gate electrode 102, a semiconductor layer 104, and a source electrode 106a and a drain electrode 106b connected to each side of the semiconductor layer 104. In addition, a channel passivation layer 105 may be further provided on the portion where the channel of the semiconductor layer 104 is located in order to prevent or reduce direct connection between the source/drain electrodes 106a and 106b and the semiconductor layer 104.

A gate insulating layer 103 is provided between the gate electrode 102 and the semiconductor layer 104.

The semiconductor layer 104 may be formed of, for example, an oxide semiconductor, amorphous silicon, polycrystalline silicon, or a combination thereof. For example, when the semiconductor layer 104 is an oxide semiconductor, the heating temperature for forming the thin film transistor may be lowered. Thus, the substrate 100 may be selected from a greater variety of available materials so that the semiconductor layer 104 may be advantageously applied to a flexible display.

In addition, the drain electrode 106b of the thin film transistor TFT may be connected to the first electrode 110 in a contact hole CT formed in the first and second passivation layers 107 and 108.

The first passivation layer 107 is provided to protect the thin film transistor TFT. Color filters 109R, 109G, and 109B may be provided thereon.

When the plurality of subpixels includes a red subpixel, a green subpixel, a blue subpixel, and a white subpixel, the color filter may include first to third color filters 109R, 109G, and 109B in each of the subpixels excluding the white subpixel W_SP. The color filters may allow the emitted white light to pass through the first electrode 110 for each wavelength. A second passivation layer 108 is formed under the first electrode 110 to cover the first to third color filters 109R, 109G, and 109B. The first electrode 110 is formed on the surface of the second passivation layer 108, excluding the contact hole CT.

Here, the configuration including the substrate 100, the thin film transistor TFT, color filters 109R, 109G, and 109B, and the first and second passivation layers 107 and 108 is referred to as a “thin film transistor array substrate” 1000.

The light emitting device OLED is formed on the thin film transistor array substrate 1000 including a bank 119, which is adjacent to a light emitting region BH. The light emitting device (OLED) includes, for example, a transparent first electrode 110, 210 a second electrode 200, 220 of a reflective electrode opposite thereto, and a first blue stack BS1, a phosphorescent stack PS and a second blue stack BS2 divided by the first and second charge generation layers CGL1 and CGL2 between the first electrode (anode) 110, 210 and the second electrode (cathode) 200, 220, as described with reference to FIGS. 1, 5, and 8. The first blue stack BS1 may include a hole injection layer (HIL) 221, a hole transport layer (HTL1) 222, an electron-blocking layer (HTL2) 223 , a first blue light emitting layer (B EML1) 224 containing a boron-based blue dopant, and an electron transport layer (ETL1) 225. The phosphorescent stack PS may include a hole transport layer HTL, HTL3, 1210, 231, a red light emitting layer (R EML) 1220, 232, a green light emitting layer (G EML) 1230, 233, and an electron transport layer (ETL) 1240, (ETL2) 234. The second blue stack BS2 may include a hole transport layer (HTL4) 241, an electron-blocking layer (HTL5) 242 , a second blue light emitting layer (B EML2) 243 containing a boron-based blue dopant, and an electron transport layer (ETL3) 244.

Of the first and the second blue stacks BS1 and BS2, the electron-blocking layer 223, 242 may contain material of Formula 2. The electron transport layer 225, 244 or an electron transport material of the blue light emitting layers 224, 243 may contain the material of Formula 1.

The first electrode 110 is divided into each subpixel. The remaining layers of the white-light emitting device OLED are integrally provided in the entire display area, rather than being divided into individual subpixels.

According to the light emitting device according to an example embodiments of the present disclosure and a light emitting display including the same, a fluorescent stack may be connected to a phosphorescent stack to form a light emitting device that realizes white. Among them, the phosphorescent stack shares the use of excitons with other phosphorescent light emitting layers in contact with the same at higher internal quantum efficiency than the fluorescent stack. The light emitting device and the light emitting display including the same according to example embodiments of the present disclosure may be capable of preventing or reducing exciton loss at the interface with the hole transport layer, and evenly distributing the generation of excitons in the adjacent phosphorescent layers. Thus, the white light emission efficiency of the adjacent phosphorescent layers may be uniformly improved by changing the material of the red light emitting layer between the hole transport layer and the other phosphorescent layer.

As a result, by balancing the efficiency between the red light emitting layer and the adjacent phosphorescent light emitting layer, the luminance of the phosphorescent light emitting layers in the white-light emitting device may be increased in a balanced way. The efficiency of the light emitting display may also be improved.

Example embodiments of the present disclosure can also be described as follows:

In example embodiments of the present disclosure, a light emitting device includes a first electrode and a second electrode facing each other, and a first blue stack, a first charge generation layer, and a phosphorescent stack disposed between the first electrode and the second electrode, wherein the phosphorescent stack includes a hole transport layer, a red light emitting layer, a green light emitting layer and an electron transport layer, wherein the red light emitting layer includes an electron transport host represented by Formula 1, a hole transport host different from the hole transport layer, and a red dopant, wherein the Formula 1 is:

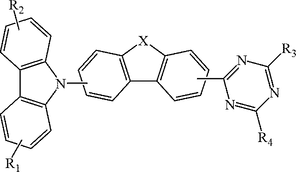

, and wherein at least one of Ri and R₂ is present, Ri optionally forms a first fused ring together with the carbazole moiety in the Formula 1, R₂ optionally forms a second fused ring together with the carbazole moiety in the Formula 1, and Ri and R₂ are each an aromatic ring, R₃ and R₄ are each selected from an aryl group, and a biphenyl group, and X is selected from N, O and S.

In some embodiments, the hole transport layer of the phosphorescent stack may include a 3,3′-biscarbazole-based compound.

In some embodiments, the first charge generation layer may include a p-type charge generation layer containing an amine-based compound doped with a fluorene-based compound, and the p-type charge generation layer may be in contact with the hole transport layer.

In some embodiments, the first charge generation layer may further include an n-type charge generation layer on a surface of the p-type charge generation layer opposite a surface of the p-type charge generation layer that is in contact with the hole transport layer, wherein the n-type charge generation layer is doped with at least one of an alkali metal, an alkaline earth metal, and a transition metal.

In some embodiments, the hole transport layer may have a thickness of 8 nm to 100 nm.

In some embodiments, the light emitting device may further include a yellow-green light emitting layer disposed between the red light emitting layer and the green light emitting layer.

In some embodiments, the electron transport host may have a triplet energy level of 2.4 eV or less.

In some embodiments, the light emitting device may further include at least one second blue stack disposed between the phosphorescent stack and the second electrode, the second blue stack may include a blue light emitting layer.

In some embodiments, Ri may be present, and Ri together with adjacent carbons in the aromatic six-membered ring in the carbazole moiety in the Formula 1 may form another aromatic six-membered ring.

In some embodiments, R₂ may be present, and R₂ together with adjacent carbons in the aromatic six-membered ring in the carbazole moiety may form another aromatic six-membered ring.

In some embodiments, R₃ and R₄ may be each independently selected from a phenyl group and a naphthyl group.

In some embodiments, R₃ may be a phenyl group.

In some embodiments, R₄ may be a phenyl group.

In some embodiments, X may be O.

In some embodiments, X may be S.

In some embodiments, R₁ may be present, and Ri is phenyl.

In some embodiments, R₂ may be present, and R₂ is phenyl.

In other example embodiments of the present disclosure, a light emitting device includes a first electrode and a second electrode facing each other, and a first blue stack, a first charge generation layer, and a phosphorescent stack disposed between the first electrode and the second electrode, wherein the phosphorescent stack includes a hole transport layer, a red light emitting layer, a green light emitting layer, and an electron transport layer, wherein the hole transport layer includes a biscarbazole-based compound, and the red light emitting layer includes an electron transport host represented by Formula 1, a hole transport host different from the hole transport layer, and a red dopant, wherein the Formula 1 is:

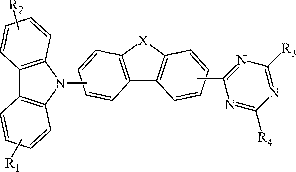

, and wherein at least one of Ri and R₂ is present, R₁ optionally forms a first fused ring together with the carbazole moiety in the Formula 1, R₂ optionally forms a second fused ring together with the carbazole moiety in the Formula 1, and Ri and R₂ are each an aromatic ring;

R₃ and R₄ are each selected from an aryl group, and a biphenyl group; and X is selected from N, O and S.

In other example embodiments of the present disclosure, a light emitting device includes a first electrode and a second electrode facing each other, and a light emitting unit disposed between the first electrode and the second electrode, the light emitting unit including a p-type charge generation layer, a hole transport layer, a first light emitting layer, a second light emitting layer, and an electron transport layer sequentially stacked, wherein the hole transport layer includes a biscarbazole-based compound, the first light emitting layer includes an electron transport host represented by Formula 1, a hole transport host different from a hole transport host of the hole transport layer, and a first dopant having an emission peak of 600 nm to 650 nm, the second light emitting layer has an emission peak that has a shorter wavelength than a wavelength of an emission peak of the first dopant, and wherein the Formula 1 is:

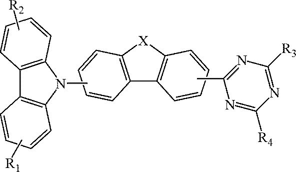

, and wherein at least one of Ri and R₂ is present, Ri optionally forms a first fused ring together with the carbazole moiety in the Formula 1, R₂ optionally forms a second fused ring together with the carbazole moiety in the Formula 1, and R₁ and R₂ are each an aromatic ring; R₃ and R₄ are each selected from an aryl group, and a biphenyl group; and X is selected from N, O and S.

In other example embodiments of the present disclosure, a light emitting display includes a substrate including a plurality of subpixels, each of the subpixels includes a thin film transistor disposed therein, and the light emitting device according to example embodiments of the present disclosure connected to the thin film transistor.

The light emitting device and the light emitting display according to the present disclosure may have the following effects.

A fluorescent stack may be connected to a phosphorescent stack to form a light emitting device that may realize white. Among them, the phosphorescent stack may share the use of excitons with other phosphorescent light emitting layers in contact with the same at higher internal quantum efficiency than the fluorescent stack. The light emitting device and the light emitting display including the same according to the present disclosure may be capable of preventing or reducing exciton loss at the interface with the hole transport layer, evenly distributing the generation of excitons in the adjacent phosphorescent layers. The white light emission efficiency of the adjacent phosphorescent layers may be uniformly improved by changing the material of the red light emitting layer between the hole transport layer and the other phosphorescent layer.

As a result, by balancing the efficiency between the red light emitting layer and the adjacent phosphorescent light emitting layer, the luminance of the phosphorescent light emitting layers in the white-light emitting device may be increased in a balanced way, and the efficiency of the light emitting display may also be improved.

It will be apparent to those skilled in the art that various modifications and variations may be made in the present disclosure without departing from the spirit or scope of the disclosure. Thus, it is intended that the present disclosure covers such modifications and variations thereto, provided they fall within the scope of the appended claims and their equivalents.

What is claimed is:

1. A light emitting device comprising:
a first electrode and a second electrode facing each other; and
a first blue stack, a first charge generation layer, and a phosphorescent stack disposed between the first electrode and the second electrode,
wherein the phosphorescent stack comprises a hole transport layer, a red light emitting layer, a green light emitting layer, and an electron transport layer,
wherein the red light emitting layer comprises an electron transport host represented by Formula 1, a hole transport host different from the hole transport layer, and a red dopant,
wherein the Formula 1 is: 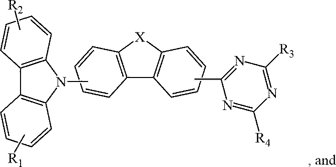
wherein at least one of R₁ and R₂ is present, R₁ optionally forms a first fused ring together with the carbazole moiety in the Formula 1, R₂ optionally forms a second fused ring together with the carbazole moiety in the Formula 1, and R₁ and R₂ are each an aromatic ring;
R₃ and R₄ are each selected from an aryl group, and a biphenyl group; and
X is selected from N, O and S.

2. The light emitting device according to claim 1, wherein the hole transport layer includes a 3,3′-biscarbazole-based compound.

3. The light emitting device according to claim 1, wherein the first charge generation layer comprises a p-type charge generation layer containing an amine-based compound doped with a fluorene-based compound, and the p-type charge generation layer is in contact with the hole transport layer.

4. The light emitting device according to claim 3, wherein the first charge generation layer further comprises an n-type charge generation layer on a surface of the p-type charge generation layer opposite a surface of the p-type charge generation layer that is in contact with the hole transport layer,
wherein the n-type charge generation layer is doped with at least one of an alkali metal, an alkaline earth metal, and a transition metal.

5. The light emitting device according to claim 1, wherein the hole transport layer has a thickness of 8 nm to 100 nm.

6. The light emitting device according to claim 1, further comprising a yellow-green light emitting layer disposed between the red light emitting layer and the green light emitting layer.

7. The light emitting device according to claim 1, wherein the electron transport host has a triplet energy level of 2.4 eV or less.

8. The light emitting device according to claim 1, further comprising at least one second blue stack disposed between the phosphorescent stack and the second electrode, the at least one second blue stack comprising a blue light emitting layer.

9. The light emitting device according to claim 1, wherein R₁ is present, and R₁ together with adjacent carbons in the aromatic six-membered ring in the carbazole moiety in the Formula 1 forms another aromatic six-membered ring.

10. The light emitting device according to claim 9, wherein R₂ is present, and R₂ together with adjacent carbons in the aromatic six-membered ring in the carbazole moiety forms another aromatic six-membered ring.

11. The light emitting device according to claim 9, wherein R₃ and R₄ are each independently selected from a phenyl group and a naphthyl group.

12. The light emitting device according to claim 1, wherein at least one of R₁ and R₂ is phenyl.

13. A light emitting device comprising:
a first electrode and a second electrode facing each other; and
a first blue stack, a first charge generation layer, and a phosphorescent stack disposed between the first electrode and the second electrode,
wherein the phosphorescent stack comprises a hole transport layer, a red light emitting layer, a green light emitting layer, and an electron transport layer,
wherein the hole transport layer comprises a biscarbazole-based compound, and the red light emitting layer comprises an electron transport host represented by Formula 1, a hole transport host different from the hole transport layer, and a red dopant,
wherein the Formula 1 is: 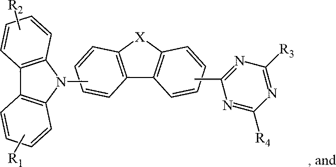
wherein at least one of R₁ and R₂ is present, R₁ optionally forms a first fused ring together with the carbazole moiety in the Formula 1, R₂ optionally forms a second fused ring together with the carbazole moiety in the Formula 1, and R₁ and R₂ are each an aromatic ring;
R₃ and R₄ are each selected from an aryl group, and a biphenyl group; and
X is selected from N, O and S.

14. The light emitting device according to claim 1, wherein the first charge generation layer comprises a p-type charge generation layer containing an amine-based compound doped with a fluorene-based compound, and the p-type charge generation layer is in contact with the hole transport layer.

15. The light emitting device according to claim 14, wherein the first charge generation layer further comprises an n-type charge generation layer on a surface of the p-type charge generation layer opposite a surface of the p-type charge generation layer that is in contact with the hole transport layer,
wherein the n-type charge generation layer is doped with at least one of an alkali metal, an alkaline earth metal, and a transition metal.

16. The light emitting device according to claim 13, wherein the hole transport layer has a thickness of 8 nm to 100 nm.

17. The light emitting device according to claim 13, further comprising a yellow-green light emitting layer disposed between the red light emitting layer and the green light emitting layer.

18. The light emitting device according to claim 13, wherein the electron transport host has a triplet energy level of 2.4 eV or less.

19. A light emitting device comprising:
a first electrode and a second electrode facing each other; and
a light emitting unit disposed between the first electrode and the second electrode, the light emitting unit comprising a p-type charge generation layer, a hole transport layer, a first light emitting layer, a second light emitting layer, and an electron transport layer sequentially stacked,
wherein the hole transport layer comprises a biscarbazole-based compound,
the first light emitting layer comprises an electron transport host represented by Formula 1, a hole transport host different from a hole transport host of the hole transport layer, and a first dopant having an emission peak of 600 nm to 650 nm, and
the second light emitting layer has an emission peak that has a shorter wavelength than a wavelength of an emission peak of the first dopant,
wherein the Formula 1 is: 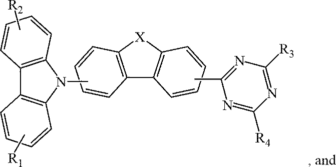
wherein at least one of R₁ and R₂ is present, R₁ optionally forms a first fused ring together with the carbazole moiety in the Formula 1, R₂ optionally forms a second fused ring together with the carbazole moiety in the Formula 1, and R₁ and R₂ are each an aromatic ring;
R₃ and R₄ are each selected from an aryl group, and a biphenyl group; and
X is selected from N, O and S.

20. A light emitting display comprising:
a substrate comprising a plurality of subpixels, each of the subpixels includes a thin film transistor disposed therein; and
the light emitting device according to claim 19 connected to the thin film transistor.
